(19) United States
(12) Patent Application Publication
(10) Pub. No.: US 2014/0335350 A1
(43) Pub. Date: Nov. 13, 2014

(54) METHOD FOR FORMING PROTECTIVE FILM ON ELECTRODE FOR TOUCH PANEL, PHOTOSENSITIVE RESIN COMPOSITION AND PHOTOSENSITIVE ELEMENT, AND METHOD FOR MANUFACTURING TOUCH PANEL

(71) Applicant: HITACHI CHEMICAL COMPANY, LTD., Chiyoda-ku, Toyko (JP)

(72) Inventors: Hiroyuki Tanaka, Hitachi-shi (JP); Yasuharu Murakami, Hitachi-shi (JP); Naoki Sasahara, Hitachi-shi (JP); Ikuo Mukai, Hitachi-shi (JP); Yoshimi Igarashi, Hitachi-shi (JP); Masahiko Ebihara, Hitachi-shi (JP); Hiroshi Yamazaki, Hitachi-shi (JP)

(21) Appl. No.: 14/362,716

(22) PCT Filed: Dec. 4, 2012
(86) PCT No.: PCT/JP2012/081377

§ 371 Date: Jun. 4, 2014

(30) Foreign Application Priority Data
Dec. 5, 2011 (JP) 2011/078104
Dec. 5, 2011 (JP) 2011/078107
Dec. 5, 2011 (JP) PCT2011/078108

(51) Int. Cl. H05K 3/28

(52) U.S. Cl. CPC H05K 3/287
USPC 428/336; 427/517; 522/39; 522/64; 428/523

(57) ABSTRACT

The method for forming a protective coat on an electrode for a touch panel according to the invention comprises a first step in which a photosensitive layer comprising a photosensitive resin composition containing a binder polymer, a photopolymerizable compound and a photopolymerization initiator is provided on a base material having an electrode for a touch panel, a second step in which prescribed sections of the photosensitive layer are cured by irradiation with active light rays, and a third step in which the sections other than the prescribed sections of the photosensitive layer are removed to form a protective coat comprising the cured sections of the photosensitive layer covering all or a portion of the electrode, wherein the hydroxyl value of the photosensitive resin composition is no greater than 40 mgKOH/g.

### TECHNICAL FIELD

The present invention relates to a method for forming a protective coat on an electrode for a touch panel, and particularly to a method for forming a protective coat suitable for protection of an electrode in an electrostatic capacitive touch panel, to a photosensitive resin composition and a photosensitive element to be used for the same, and to a method for manufacturing a touch panel.

### BACKGROUND ART

Liquid crystal display units and touch panels (touch sensors) are used in display devices including large electronic devices such as personal computers and televisions and miniature electronic devices such as car navigation systems, cellular phones and electronic dictionaries or OA.FA devices. Such liquid crystal display units and touch panels are provided with electrodes composed of transparent conductive electrode materials. As transparent conductive electrode materials there are known ITO (Indium-Tin-Oxide), indium oxide and tin oxide, which materials exhibit high visible light transmittance and are therefore the major materials used as electrode materials for liquid crystal display unit boards.

Various types of systems are already being implemented for touch panels, but in recent years the use of electrostatic capacitive touch panels has been progressing. In an electrostatic capacitive touch panel, contact of the fingertip (a conductor) with the touch input screen causes electrostatic capacitive coupling between the fingertip and the conductive film, forming a condenser. Thus, an electrostatic capacitive touch panel detects changes in electrical charge at sites of contact with the fingertip, thereby determining the coordinates.

In particular, projection-type electrostatic capacitive touch panels have satisfactory operativity allowing complex instructions to be carried out since they allow multipoint fingertip detections, and the excellent operativity has led to their utilization as input devices on the display surfaces of devices with small displays such as cellular phones, portable music players and the like.

For representation of two-dimensional coordinates with an X-axis and a Y-axis, a projection-type electrostatic capacitive touch panel generally has a plurality of X-electrodes and a plurality of Y-electrodes perpendicular to the X-electrode forming a two-layer structure, with ITO (Indium-Tin-Oxide) employed as the electrodes.

Incidentally, since the frame region of a touch panel is a region where detection of the touch location is not possible, reducing the area of the frame region has been an important goal in order to increase product value. The frame region requires metal wiring in order to transmit the detection signal of a touch location, but the width of the metal wiring must be narrowed to reduce the frame area. Because of the insufficiently high conductivity of ITO, metal wirings are generally formed of copper.

However, in the touch panels mentioned above, corrosive components such as moisture and salts can infiltrate from the sensing region into the interior upon contact with the fingertip. When corrosive components infiltrate into the interior of a touch panel, the metal wiring may corrode, electrical resistance between the electrodes and driving circuits may increase, and wire breakage can occur.

In order to prevent corrosion of metal wirings, there have been disclosed electrostatic capacitive projection-type touch panels with insulating layers formed on metals (Patent document 1, for example). In such touch panels, a silicon dioxide layer is formed on metal by a plasma chemical, vapor deposition method (plasma CVD), thereby preventing corrosion of the metal. However, because such methods employ plasma CVD, they require high-temperature treatment, and therefore the base materials are limited and production cost is increased.

Incidentally, known methods for providing resist films on necessary locations include methods in which a photosensitive layer comprising a photosensitive resin composition is provided on a prescribed base material and the photosensitive layer is exposed and developed (Patent documents 2 to 4, for example).

### CITATION LIST

### Patent Literature

[Patent document 1] Japanese Unexamined Patent Application Publication No. 2011-28594
[Patent document 2] Japanese Unexamined Patent Application Publication HEI No. 7-253666
[Patent document 3] Japanese Unexamined Patent Application Publication No. 2005-99647
[Patent document 4] Japanese Unexamined Patent Application Publication HEI No. 11-133617

### SUMMARY OF INVENTION

### Technical Problem

Fabrication of a protective coat by a photosensitive resin composition can potentially reduce cost compared to plasma CVD. However, when a protective coat is to be formed on an electrode for a touch panel, a large thickness of the protective coat can result in conspicuous level differences between locations with the coat and locations without the coat. The protective coat is therefore preferred to be as thin as possible. However, the rust resistance of coats formed from photosensitive resin compositions has not been studied for thicknesses on the level of 10 μm and smaller.

It is an object of the present invention to provide a method for forming a protective coat on an electrode for a touch panel that allows formation of a protective coat with sufficient rust resistance on a desired electrode for a touch panel even as a thin-film, as well as a photosensitive resin composition and photosensitive element that allow formation of such a protective coat, and a method for manufacturing a touch panel.

### Solution to Problem

As a result of much diligent research carried out with the aim of solving the problems described above, the present inventors have found that by adjusting the hydroxyl value of a photosensitive resin composition comprising a binder polymer, a photopolymerizable compound and a photopolymerization initiator, it is possible to ensure developability while exhibiting adequate rust resistance even when the film formed by photocuring has a thickness of 10 μm or smaller, and to adequately prevent corrosion of metals such as copper, and we have thereupon completed this invention.

According to a first aspect, the invention provides a method for forming a protective coat on an electrode for a touch panel comprising a first step in which a photosensitive layer comprising a photosensitive resin composition containing a binder polymer, a photopolymerizable compound and a photopolymerization initiator is provided on a base material having an electrode for a touch panel, a second step in which prescribed sections of the photosensitive layer are cured by irradiation with active light rays, and a third step in which the sections other than the prescribed sections of the photosensitive layer are removed to form a protective coat comprising the cured sections of the photosensitive layer covering all or a portion of the electrode, wherein the hydroxyl value of the photosensitive resin composition is no greater than 40 mgKOH/g.

In the method for forming a protective coat on an electrode for a touch panel according to the first aspect of the invention, using the specified photosensitive resin composition ensures developability and adhesiveness on the base material, while allowing formation of a protective coat that has adequate rust resistance even with a thickness of 10 μm or smaller. According to the invention it is possible to use a photosensitive resin composition to form a protective coat having sufficient aesthetic appearance and rust resistance, thereby making it possible to reduce production cost for production of touch panels.

For the first aspect, the hydroxyl value of the binder polymer is preferably no greater than 50 mgKOH/g from the viewpoint of improving the rust resistance of the protective coat.

According to the first aspect, the hydroxyl value of the photopolymerizable compound is preferably no greater than 90 mgKOH/g from the viewpoint of further improving the rust resistance of the protective coat.

Also, the acid value of the binder polymer is preferably no greater than 120 mgKOH/g from the viewpoint of still further improving the rust resistance of the protective coat.

From the viewpoint of both adhesiveness and rust resistance, the photosensitive resin composition preferably further comprises a phosphoric acid ester that includes a photopolymerizable unsaturated bond.

From the viewpoint of sufficient visibility of the touch panel, the photosensitive layer preferably has a minimum visible light transmittance of 90% or greater at 400 to 700 nm. In this case the method for forming a protective coat on an electrode for a touch panel according to the first aspect of the invention will be suitable for forming a protective coat covering an electrode in a sensing region.

Also, from the viewpoint of further improving the developability, the photosensitive resin composition preferably further comprises one or more compounds selected from the group consisting of triazole compounds with mercapto groups, tetrazole compounds with mercapto groups, thiadiazole compounds with mercapto groups, triazole compounds with amino groups and tetrazole compounds with amino groups. This can reduce development residue and facilitate formation of a protective coat with a satisfactory pattern.

According to the first aspect, the photopolymerization initiator preferably contains an oxime ester compound and/or a phosphine oxide compound. By containing an oxime ester compound or a phosphine oxide compound as the photoinitiator, it will be possible to form a pattern with sufficient resolution even when the photosensitive layer is thin.

In consideration of visibility and aesthetic appearance of the touch panel, a higher transparency is preferred for the protective coat. Conversely, however, the present inventors have found that when patterning a thin photosensitive layer with high transparency, the resolution tends to be reduced. The present inventors believe that the cause of this is that a smaller photosensitive layer thickness increases the effect of light scattering through the base material, generating halation.

It is difficult to ensure transparency in a conventional photosensitive resin composition in which the photosensitive property is controlled with a pigment or dye.

According to the invention, however, the photopolymerization initiator contains an oxime ester compound and/or a phosphine oxide compound, thereby allowing pattern formation with adequate resolution.

The present inventors presume that the reason for this effect to be that the oxime site in the oxime ester compound or the phosphine oxide site in the phosphine oxide compound has relatively high photodecomposition efficiency and a suitable threshold value such that it does not decompose with scant levels of leaked light, and therefore the effect of leaked light is minimized.

Furthermore, according to the first aspect of the invention, the first step is preferably a step in which there is prepared a photosensitive element comprising a support film and a photosensitive layer composed of the aforementioned photosensitive resin composition provided on the support film, and the photosensitive layer of the photosensitive element is transferred onto the base material to provide the photosensitive layer. By thus using a photosensitive element, it is possible to significantly contribute to shortening of the production process and reduction of costs, by allowing a roll-to-roll process to be easily accomplished and by shortening the solvent drying step, for example.

As a second aspect, the invention further provides a photosensitive resin composition comprising a binder polymer, a photopolymerizable compound and a photopolymerization initiator, wherein the hydroxyl value of the photosensitive resin composition is no greater than 40 mgKOH/g and the photosensitive resin composition is used to form a protective coat on an electrode for a touch panel.

With a photosensitive resin composition according to the second aspect of the invention, it is possible to form a protective coat having adequate rust resistance even as a thin-film, on a prescribed electrode for a touch panel.

For the second aspect, the hydroxyl value of the binder polymer component is preferably no greater than 50 mgKOH/g from the viewpoint of improving the rust resistance of the protective coat.

According to the second aspect, the hydroxyl value of the photopolymerizable compound component is preferably no greater than 90 mgKOH/g from the viewpoint of further improving the rust resistance of the protective coat.

Also, the acid value of the binder polymer component is preferably no greater than 120 mgKOH/g from the viewpoint of still further improving the rust resistance of the protective coat.

From the viewpoint of both adhesiveness and developability, the photosensitive resin composition according to the second aspect of the invention preferably further comprises a phosphoric acid ester that includes a photopolymerizable unsaturated bond.

From the viewpoint of sufficient visibility of the touch panel, the photosensitive resin composition according to the second aspect of the invention preferably has a minimum visible light transmittance of 90% or greater at 400 to 700 nm.

From the viewpoint of further improving the developability, the photosensitive resin composition according to the second aspect of the invention preferably further comprises one or more compounds selected from the group consisting of triazole compounds with mercapto groups, tetrazole compounds with mercapto groups, thiadiazole compounds with mercapto groups, triazole compounds with amino groups and tetrazole compounds with amino groups. This can reduce development residue and facilitate formation of a protective coat with a satisfactory pattern.

Furthermore, in the photosensitive resin composition according to the second aspect of the invention, the photopolymerization initiator preferably contains an oxime ester compound and/or a phosphine oxide compound. This will allow formation of a thin protective coat with high transparency, in a pattern having sufficient resolution.

As a third aspect, the invention further provides a photosensitive element comprising a support film, and a photosensitive layer composed of the photosensitive resin composition according to the second aspect of the invention, formed on the support film.

With the photosensitive element according to the third aspect of the invention, it is possible to form a protective coat having adequate rust resistance even as a thin-film, on a prescribed electrode for a touch panel.

The thickness of the photosensitive layer may be 10 μm or smaller.

As a fourth aspect, the invention further provides a method for manufacturing a touch panel, comprising a step of forming, on a base material with an electrode for a touch panel, a protective coat covering all or a portion of the electrode by the method for forming a protective coat according to the first aspect of the invention.

### Advantageous Effects of Invention

According to the invention it is possible to provide a method for forming a protective coat on an electrode for a touch panel that allows formation of a protective coat with sufficient rust resistance on a desired electrode for a touch panel even as a thin-coat, as well as a photosensitive resin composition and photosensitive element that allow formation of such a protective coat, and a method for manufacturing a touch panel.

Furthermore, according to the invention it is possible to protect the metal electrodes of electrical capacitance-type touch panels. Also according to the invention it is possible to protect electrodes in the frame regions of touch panels that have increased conductivity by formation of metal layers of copper or the like, that are prone to rusting by moisture or salts.

### BRIEF DESCRIPTION OF DRAWINGS

FIG. 1 is a schematic cross-sectional view showing an embodiment of a photosensitive element of the invention.

FIG. 2 is a schematic cross-sectional view for illustration of an embodiment of a method for forming a protective coat on an electrode for a touch panel according to the invention.

FIG. 3 is a schematic top view showing an example of an electrostatic capacitive touch panel.

FIG. 4 is a schematic top view showing another example of an electrostatic capacitive touch panel.

FIG. 5(a) is a partial cross-sectional view of section C of FIG. 3 along line V-V, and (b) is a partial cross-sectional view showing another mode thereof.

### DESCRIPTION OF EMBODIMENTS

Embodiments for carrying out the invention will now be explained in further detail. However, the present invention is not limited to the embodiments described below.

If the object is form a protective coat with excellent transparency and rust resistance to protect electrode-formed locations of a touch panel (touch sensor), the photosensitive resin composition of the invention can be suitably used regardless of changes to the structure of the touch panel. Specifically, it can be suitably used when the purpose is to protect the electrode-formed locations of a touch panel (touch sensor), in cases where the touch panel structure has been changed from a 3-layer structure comprising a cover glass, a touch panel and a liquid crystal panel, to a cover glass integrated type or on-cell type.

As used herein, the term “electrode for a touch panel” includes not only the electrode in the sensing region of a touch panel, but also the metal wiring in the frame region. The protective coat may be provided for one or both electrodes.

Also as used herein, “excellent transparency” means 90% or greater permeation of visible light of 400 to 700 nm, and it includes the concept of transparency even with some degree of light scattering.

Also, “(meth)acrylic acid” refers to acrylic acid or methacrylic acid, “(meth)acrylate” refers to acrylate or its corresponding methacrylate, and “(meth)acryloyl group” refers to an acryloyl or methacryloyl group. Also, “(poly)oxyethylene chain” refers to an oxyethylene or polyoxyethylene group, and “(poly)oxypropylene chain” refers to an oxypropylene or polyoxypropylene group. The term “(EO)-modified” refers to a compound with a (poly)oxyethylene chain, the term “(PO)-modified” refers to a compound with a (poly)oxypropylene chain, and “(EO.PO)-modified” refers to a compound with both a (poly)oxyethylene chain and a (poly)oxypropylene chain.

Also as used herein, the term “step” includes not only an independent step, but also cases where it cannot be clearly distinguished from other steps, so long as the desired effect of the step can be achieved. As used herein, a numerical range using “to” represents a range including the numerical values specified as the minimum and maximum values for the range.

Also, the contents of the components in compositions referred to herein, in cases where the composition contains more than one substance corresponding to each component in the composition, are the total amounts of those substances in the composition, unless otherwise specified,

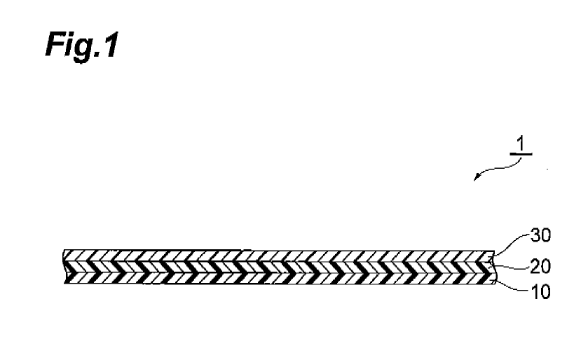

FIG. 1 is a schematic cross-sectional view showing an embodiment of a photosensitive element of the invention. The photosensitive element 1 shown in FIG. 1 comprises a support film 10, a photosensitive layer 20 composed of a photosensitive resin composition according to the invention formed on the support film 10, and a protective film 30 formed on the side of the photosensitive layer 20 opposite the support film 10.

The photosensitive element 1 of this embodiment can be suitably used to form a protective coat on an electrode for a touch panel.

The support film 10 used may be a polymer film. Examples of polymer films include films made of polyethylene terephthalate, polycarbonate, polyethylene, polypropylene, polyethersulfone and the like.

The thickness of the support film 10 is preferably 5 to 100 μm, more preferably 10 to 70 μm, even more preferably 15 to 40 μm and most preferably 20 to 35 μm, from the viewpoint of ensuring coverability and minimizing reduction in resolution during irradiation with active light rays through the support film 10.

The photosensitive resin composition of the invention that is to form the photosensitive layer 20 contains a binder polymer (hereunder referred to as component (A)), a photopolymerizable compound (hereunder referred to as component (B)) and a photopolymerization initiator (hereunder referred to as component (C)), and the hydroxyl value of the photosensitive resin composition is no greater than 40 mgKOH/g. If the protective coat used is a coat comprising a photosensitive resin composition having a hydroxyl value within this range, it can exhibit adequate rust resistance even at thicknesses of 10 μm and smaller. The photosensitive resin composition of this embodiment can form a protective coat capable of exhibiting both an aesthetic appearance and rust resistance.

The hydroxyl value of the photosensitive resin composition can be measured in the following manner.

First, 1 g of photosensitive resin composition is precisely weighed out as a sample for measurement of the hydroxyl value. To the precisely weighed photosensitive resin composition there is added 10 mL of a 10 mass % acetic anhydride/pyridine solution, and the components are uniformly dissolved and heated at 100° C. for 1 hour. After heating, 10 mL of water and 10 mL of pyridine are added and heating is continued at 100° C. for 10 minutes. An automatic titrator (“COM-1700” by Hiranuma Sangyo Corp.) is then used for measurement by neutralization titration with a 0.5 mol/L ethanol solution of potassium hydroxide.

The hydroxyl value can be calculated by the following formula.

Hydroxyl value=(A−B)×f×28.05/sample(g)+acid value

In the formula, A represents the amount (mL) of 0.5 mol/L potassium hydroxide ethanol solution used for the blank test, B represents the amount (mL) of 0.5 mol/L potassium hydroxide ethanol solution used for titration, and f represents the factor.

When the measuring solution is a coating solution, containing the photosensitive resin composition and a solvent, the hydroxyl value of the photosensitive resin composition is measured after previously removing the solvent. Specifically, before weighing out 1 g of the photosensitive resin composition whose hydroxyl value is to be measured, the coating solution is heated for 1 to 4 hours at a temperature at least 10° C. higher than the boiling point of the solvent, to remove the solvent.

Also, the hydroxyl value of the photosensitive layer 20 in the photosensitive element described hereunder can be measured in the following manner. First, after layering the photosensitive element several times on the glass panel, superposing only the photosensitive layers of the photosensitive elements, the photosensitive resin composition that is to form the photosensitive layer 20 for measurement of the hydroxyl value is scraped off with a metal spatula and 1 g is weighed out. The weighed out photosensitive resin composition is transferred to an Erlenmeyer flask, 10 mL of a 10 mass % acetic anhydride/pyridine solution is added, and the mixture is uniformly dissolved and heated at 100° C. for 1 hour. After heating, 10 mL of water and 10 mL of pyridine are added and heating is continued at 100° C. for 10 minutes. An automatic titrator (“COM-1700” by Hiranuma Sangyo Corp.) may then be used for measurement by neutralization titration with a 0.5 mol/L ethanol solution of potassium hydroxide.

The following is conjectured by the present inventors to be the reason why an effect is obtainable of exhibiting adequate rust resistance even with thin-coats. The present inventors believe that when a photosensitive resin composition has been used to form a thin-coat of 10 μm or smaller, corrosive components such as moisture and salts easily enter into the coat, and this tendency farther increases depending on the hydroxyl and especially hydroxyalkyl groups in the photosensitive resin composition. It is believed that, with this embodiment, limiting the hydroxyl value of all of the components forming the protective coat of the photosensitive resin composition to within the range specified above was able to adequately minimize reduction in rust resistance by hydroxyl groups.

The binder polymer as component (A) can be used without any particular restrictions so long as the hydroxyl value of the photosensitive resin composition is in the range of no greater than 40 mgKOH/g. From the viewpoint of excellent rust resistance of the protective coat, the hydroxyl value of component (A) is preferably no greater than 50 mgKOH/g and more preferably no greater than 45 mgKOH/g.

The hydroxyl value of component (A) can be determined in the same manner as measurement of the hydroxyl value of the binder polymer as described above, after weighing out 1 g of binder polymer for measurement of the hydroxyl value. When the binder polymer is added in admixture with a synthetic solvent or diluting solvent, it is first heated for 1 to 4 hours at a temperature at least 10° C. higher than the boiling point of the synthetic solvent or diluting solvent to remove the solvent, before measuring the hydroxyl value.

Component (A) may be, for example, a polymer with carboxyl groups.

Among polymers with carboxyl groups, component (A) is preferably a copolymer containing a structural unit derived from (a) (meth)acrylic acid and (b) an alkyl (meth)acrylate ester.

Examples for the (b) alkyl (meth)acrylate include methyl (meth)acrylate, ethyl (meth)acrylate, butyl (meth)acrylate, 2-ethylhexyl (meth)acrylate, dicyclopentanyl (meth)acrylate, and hydroxylethyl (meth)acrylate.

When using an alkyl (meth)acrylate containing a hydroxyl group, such as hydroxylethyl (meth)acrylate, the hydroxyl value of component (A) is preferably adjusted to be no greater than 50 mgKOH/g, more preferably adjusted to be no greater than 45 mgKOH/g and even more preferably adjusted to be no greater than 40 mgKOH/g.

The copolymer may also contain in the structural unit another monomer that is copolymerizable with component (a) and/or component (b).

Examples of other monomers that are copolymerizable with component (a) and/or component (b) include tetrahydrofurfuryl (meth)acrylate, dimethylaminoethyl (meth)acrylate, diethylaminoethyl (meth)acrylate, glycidyl (meth)acrylate, benzyl (meth)acrylate, 2,2,2-trifluoroethyl (meth)acrylate, 2,2,3,3-tetrafluoropropyl (meth)acrylate, (2-isocyanatoethyl) (meth)acrylate, (meth)acrylamide, (meta)acrylonitrile, diacetone (meth)acryl amide, N-cyclohexylmaleimide, styrene and vinyltoluene. For synthesis of a binder polymer as component (A), the monomer component used may be of a single type or a combination of two or more types.

The molecular weight of the binder polymer as component (A) is not particularly restricted, but from the viewpoint of coatability, coated film strength and developability, for most cases the weight-average molecular weight is preferably 10,000 to 200,000, more preferably 30,000 to 150,000 and most preferably 50,000 to 100,000. The measuring conditions for the weight-average molecular weight are the same measuring conditions as in the examples of the present specification.

The acid value of the binder polymer as component (A) is preferably no greater than 120 mgKOH/g from the viewpoint of allowing development with various known developing solutions during the developing step, and improving resistance to corrosive components such as moisture and salts when it is to function as a protective coat for an electrode.

Also, when development is to be carried out using an aqueous alkali solution such as sodium carbonate, potassium carbonate, tetramethylammonium hydroxide or triethanolamine, the acid value of component (A) is preferably 50 to 120 mgKOH/g. From the viewpoint of excellent developability, it is preferably 50 mgKOH/g or greater, more preferably 60 mgKOH/g or greater and even more preferably 70 mgKOH/g or greater. For protection of an electrode for a touch panel, it is preferably no greater than 120 mgKOH/g from the viewpoint of protecting the electrode from corrosive components such as moisture and salts.

The acid value of the binder polymer as component (A) can be measured in the following manner. A 1 g portion of binder polymer for measurement of the acid value is precisely weighed out.

A 30 g portion of acetone is added to the binder polymer to homogeneously dissolve it. Next, an appropriate amount of phenolphthalein is added to the solution as an indicator, and a 0.1N KOH aqueous solution is used for titration to allow measurement of the acid value. The acid value can be calculated by the following formula.

Acid value=0.1×Vf×56.1/(Wp×I)

In the formula, Vf represents the titer (mL) of the KOH aqueous solution, Wp represents the weight (g) of the measured resin solution, and I represents the ratio (mass %) of nonvolatile components in the measured resin solution.

When the binder polymer is added in admixture with a synthetic solvent or diluting solvent, it is first heated for 1 to 4 hours at a temperature at least 10° C. higher than the boiling point of the synthetic solvent or diluting solvent to remove the solvent, before measuring the acid value.

The photopolymerizable compound as component (B) can be used without any particular restrictions depending on the required properties, so long as the hydroxyl value of the photosensitive resin composition is no greater than 40 mgKOH/g. The hydroxyl value of component (B) is preferably no greater than 90 mgKOH/g and more preferably no greater than 60 mgKOH/g.

The hydroxyl value of the photopolymerizable compound as component (B) is determined by precisely weighing out 1 g of the photopolymerizable compound whose hydroxyl value is to be measured, and performing measurement in the same manner as for measurement of the hydroxyl value of the photosensitive resin composition. When the photopolymerizable compound is added in admixture with a synthetic solvent or diluting solvent, it is first heated for 1 to 4 hours at a temperature at least 10° C. higher than the boiling point of the synthetic solvent or diluting solvent to remove the solvent, before measuring the acid value.

The photopolymerizable compound used as component (B) may be a photopolymerizable compound with an ethylenic unsaturated group.

Examples of photopolymerizable compounds with ethylenic unsaturated groups include monofunctional vinyl monomers, bifunctional vinyl monomers and polyfunctional vinyl monomers having at least three polymerizable ethylenic unsaturated groups.

Examples of monofunctional vinyl monomers include (meth)acrylic acid, alkyl (meth)acrylate and monomers that are copolymerizable therewith, which were mentioned as monomers to be used for synthesis of the suitable examples of copolymers for component (A).

Examples of bifunctional vinyl monomers include polyethylene glycol di(meth)acrylate, trimethylolpropane di(meth)acrylate, polypropylene glycol di(meth)acrylate, bisphenol A polyoxyethylenedipolyoxypropylene di(meth)acrylate (2,2-bis(4-(meth)acryloxypolyethoxypolypropoxyphenyl)propane), bisphenol A diglycidylether di(meth)acrylate, and ester compounds of polybasic carboxylic acids (such as phthalic anhydride) and substances having a hydroxyl group and an ethylenic unsaturated group β-hydroxyethyl acrylate, β-hydroxyethyl methacrylate and the like).

Examples of polyfunctional vinyl monomers having at least three polymerizable ethylenic unsaturated groups include compounds obtained by reacting α,β-unsaturated saturated carboxylic acids with polyhydric alcohols, such as trimethylolpropane tri(meth)acrylate, tetramethylolmethane tri(meth)acrylate, tetramethylolmethane tetra(meth)acrylate, dipentaerythritol penta(meth)acrylate and dipentaerythritol hexa(meth)acrylate, and compounds obtained by adding α,β-unsaturated carboxylic acids to glycidyl group-containing compounds, such as trimethylolpropane-triglycidyl ether triacrylate.

Among these, component (B) is preferably one containing a polyfunctional vinyl monomer having at least three polymerizable ethylenic unsaturated groups. From the viewpoint of minimizing electrode corrosion and facilitating development, there are preferred one or more selected from among (meth)acrylate compounds having a pentaerythritol-derived backbone, (meth)acrylate compounds having a dipentaerythritol-derived backbone and (meth)acrylate compounds having a trimethylolpropane-derived backbone, and more preferred are one or more selected from among (meth)acrylate compounds having a dipentaerythritol-derived backbone and (meth)acrylate compounds having a trimethylolpropane-derived backbone.

A (meth)acrylate having a dipentaerythritol-derived backbone is an ester compound of dipentaerythritol and (meth)acrylic acid, and such ester compounds include compounds modified with alkyleneoxy groups. These ester compounds preferably have 6 ester bonds per molecule, but they may be mixtures of compounds with 1-5 ester bonds.

Also, a (meth)acrylate compound having a trimethylolpropane-derived backbone is an ester compound of trimethylolpropane and (meth)acrylic acid, and such ester compounds include compounds modified with alkyleneoxy groups. These ester compounds preferably have 3 ester bonds per molecule, but they may be mixtures of compounds with 1-2 ester bonds.

Among polyfunctional vinyl monomers having at least three polymerizable ethylenic unsaturated groups, there are preferred one or more compounds selected from among alkylene oxide-modified trimethylolpropane (meth)acrylate compounds, alkylene oxide-modified tetramethylolmethane (meth)acrylate compounds, alkylene oxide-modified pentaerythritol (meth)acrylate compounds, alkylene oxide-modified dipentaerythritol (meth)acrylate compounds, alkylene oxide-modified glycerin (meth)acrylate compounds and alkylene oxide-modified trimethylolpropane-triglycidyl ether (meth)acrylate compounds, and there are more preferred one or more compounds selected from among alkylene oxide-modified dipentaerythritol (meth)acrylate compounds and alkylene oxide-modified trimethylolpropane (meth)acrylate compounds, from the viewpoint of minimizing electrode corrosion and further facilitating development.

BO-modified pentaerythritol tetraacrylate, for example, may be used as the alkylene oxide-modified tetramethylolmethane (meth)acrylate compound. BO-modified pentaerythritol tetraacrylate is available as RP-1040 (product of Nippon Kayaku Co., Ltd.).

These compounds may be used alone or in combinations of two or more different ones.

When a polyfunctional vinyl monomer having at least three polymerizable ethylenic unsaturated groups in the molecule is to be used in combination with a monofunctional vinyl monomer or a bifunctional vinyl monomer, there are no particular restrictions on the proportion in which they are used, but from the viewpoint of the photocuring property and minimizing electrode corrosion, the proportion of the polyfunctional vinyl monomer having at least three polymerizable ethylenic unsaturated groups in the molecule is preferably 30 parts by mass or greater, more preferably 50 parts by mass or greater and even more preferably 75 parts by mass or greater, with respect to 100 parts by mass as the total of the photopolymerizable compound in the photosensitive resin composition.

The content of component (A) and component (B) in the photosensitive resin composition of this embodiment is preferably 40-80 parts by mass of component (A) and 20-60 parts by mass of component (B), more preferably 50-70 parts by mass of component (A) and 30-50 parts by mass of component (B) and even more preferably 55-65 parts by mass of component (A) and 35-45 parts by mass of component (B), with respect to 100 parts by mass as the total of component (A) and component (B).

If the contents of component (A) and component (B) are within this range, it will be possible to obtain adequate sensitivity while guaranteeing sufficient coatability or film properties of the photosensitive element, and to adequately ensure the photocuring property, developability and electrode corrosion.

Examples for the photopolymerization initiator as component (C) include aromatic ketones such as benzophenone, N,N,N′,N′-tetramethyl-4,4′-diaminobenzophenone (Michler's ketone), N,N,N′,N′-tetraethyl-4,4′-diaminobenzophenone, 4-methoxy-4′-dimethylaminobenzophenone and 2-benzyl-2-dimethylamino-1-(4-morpholinophenyl)-butanone-1,2-methyl-1-[4-(methylthio)phenyl]-2-morpholino-propanone-1; benzoinether compounds such as benzoinmethyl ether, benzoinethyl ether and benzoinphenyl ether; benzoin compounds such as benzoin, methylbenzoin and ethylbenzoin; oxime ester compounds such as 1,2-octanedione, 1-[4-(phenylthio)-, 2-(O-benzoyloxime)], ethanone, 1-[9-ethyl-6-(2-methylbenzoyl)-9H-carbazol-3-yl]-, 1-(O-acetyloxime); benzyl derivatives such as benzyldimethylketal; acridine derivatives such as 9-phenylacridine and 1,7-bis(9,9′-acridinyl)heptane; N-phenylglycine derivatives such as N-phenylglycine; coumarin compound; oxazole compound; and phosphine oxide compounds such as 2,4,6-trimethylbenzoyl-diphenyl-phosphine oxide.

Of these, oxime ester compounds and/or phosphine oxide compounds are preferred for transparency of the formed protective coat and pattern formability with coat thicknesses of 10 μm and smaller.

The present inventors have found that, although higher protective coat transparency is preferred from the viewpoint of visibility and aesthetic appearance of the touch panel, the resolution tends to be reduced when patterning a thin photosensitive layer with high transparency. The present inventors believe that the cause of this is that a smaller photosensitive layer thickness increases the effect of light scattering through the base material, generating halation. In contrast, the presence of one of the aforementioned compounds as component (C) allows formation of a pattern with adequate resolution even when patterning a thin photosensitive layer with high transparency.

The present inventors presume that the reason for this effect to be that the oxime site in the oxime ester compound or the phosphine oxide site in the phosphine oxide compound has relatively high photo decomposition efficiency and a suitable threshold value such that it does not decompose with scant levels of leaked light, and therefore the effect of leaked light is minimized.

Oxime ester compounds include compounds represented by the following formulas (C-1) and formula (C-2), but compounds represented by the following formula (C-1) are preferred from the viewpoint of fast-curing properties and transparency.

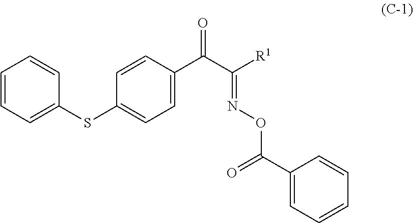

In formula (C-1), R¹ represents a C1-12 alkyl or C3-20 cycloalkyl group. So long as the effect of the invention is not impeded, a substituent may be present on the aromatic ring in formula (C-1).

In formula (C-1), R¹ is preferably a C3-10 alkyl or C4-15 cycloalkyl group, and more preferably a C4-8 alkyl or C4-10 cycloalkyl group.

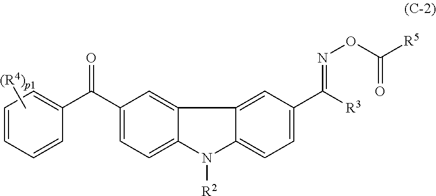

In formula (C-2), R² represents hydrogen or a C1-12 alkyl group, R³ represents a C1-12 alkyl or C3-20 cycloalkyl group, R⁴ represents a C1-12 alkyl group and R⁵ represents a C1-20 alkyl or aryl group. The symbol p1 represents an integer of 0-3. When p1 is 2 or greater, the multiple R⁴ groups may be the same or different. The carbazole ring may also have a substituent so long as the effect of the invention is not impeded.

In formula (C-2), R² is preferably a C1-8 alkyl group, more preferably a C1-4 alkyl group and even more preferably an ethyl group.

In formula (C-2), R³ is preferably a C1-8 alkyl or C4-15 cycloalkyl group, and more preferably a C1-4 alkyl or C4-10 cycloalkyl group.

The compound represented by formula (C-1) may be 1,2-octanedione, 1-[4-(phenylthio)-, 2-(O-benzoyloxime)] or the like. The compound represented by formula (C-2) may be ethanone, 1-[9-ethyl-6-(2-methylbenzoyl)-9H-carbazol-3-yl]-, 1-(O-acetyloxime) or the like. The compound 1,2-octanedione, 1-[4-(phenylthio)-, 2-(O-benzoyloxime)] is available as IRGACURE OXE 01 (trade name of BASF Corp.). Also, ethanone, 1-[9-ethyl-6-(2-methylbenzoyl)-9H-carbazol-3-yl]-, 1-(O-acetyloxime) is commercially available as IRGACURE OXE 02 (trade name of BASF Corp.). They may be used alone or in combinations of two or more.

The compound 1,2-octanedione, 1-[4-(phenylthio)-, 2-(O-benzoyloxime)] is especially preferred for formula (C-1). Particularly preferred for formula (C-2) is ethanone, 1-[9-ethyl-6-(2-methylbenzoyl)-9H-carbazol-3-yl]-, 1-(O-acetyloxime).

The phosphine oxide compound may be a compound represented by the following formula (C-3) or formula (C-4). From the viewpoint of fast-curing properties and transparency, a compound represented by the following formula (C-3) is preferred.

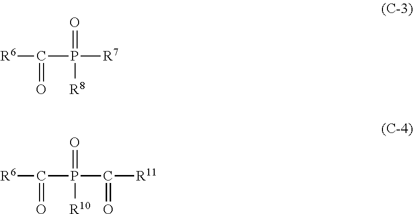

In formula (C-3), R⁶, R⁷ and R⁸ each independently represent a C1-20 alkyl or aryl group. In formula (C-4), R⁹, R¹⁰ and R¹¹ each independently represent a C1-20 alkyl or aryl group.

When R⁶, R⁷ or R⁸ in formula (C-3) is a C1-20 alkyl group, or when R⁹, R¹⁰ or R¹¹ in formula (C-4) is a C1-20 alkyl group, the alkyl group may be straight-chain, branched-chain, or cyclic, and more preferably the number of carbon atoms of the alkyl group is 5-10.

When R⁶, R⁷ or R⁸ in formula (C-3) is an aryl group or when R⁹, R¹⁰ or R¹¹ in formula (C-4) is an aryl group, the aryl group may be optionally substituted. Examples of substituents include C1-6 alkyl and C1-4 alkoxy groups.

Of these, R⁶, R⁷ and R⁸ in formula (C-3) are preferably aryl groups. Also, R⁹, R¹⁰ and R¹¹ in formula (C-4) are preferably aryl groups.

The compound represented by formula (C-3) is preferably 2,4,6-trimethylbenzoyl-diphenyl-phosphine oxide, in consideration of transparency of the protective coat to be formed and pattern formability with a film thickness of 10 μm or smaller. The compound 2,4,6-trimethylbenzoyl-diphenyl-phosphine oxide is commercially available as LUCIRIN TPO (trade name of BASF Corp.), for example.

The content of the photopolymerization initiator as component (C) is preferably 0.1 to 20 parts by mass, more preferably 1 to 10 parts by mass and more preferably 2 to 5 parts by mass, with respect to 100 parts by mass as the total of component (A) and component (B).

If the content of component (C) is within this range it will be possible to obtain sufficient photosensitivity while also minimizing problems such as increasing absorption on the surface of the composition upon irradiation with active light rays that results in incomplete photocuring of the interior, or reduced visible light transmittance.

From the viewpoint of avoiding generation of development residue on the metal surface that is to be removed, the photosensitive resin composition of this embodiment preferably further comprises one or more compounds selected from the group consisting of triazole compounds with mercapto groups, tetrazole compounds with mercapto groups, thiadiazole compounds with mercapto groups, triazole compounds with amino groups and tetrazole compounds with amino groups (hereunder also referred to as component (D)).

An example of a triazole compound with a mercapto group is 3-mercapto-triazole (3MT, trade name of Wako Pure Chemical Industries, Ltd.). An example of a tetrazole compound with a mercapto group is 1-methyl-5-mercapto-1H-tetrazole (MMT, trade name of Toyobo, Ltd.). An example of a thiadiazole compound with a mercapto group is 2-amino-5-mercapto-1,3,4-thiadiazole (ATT, trade name of Wako Pure Chemical Industries, Ltd.).

Triazole compounds with amino groups include compounds such as benzotriazole, 1H-benzotriazole-1-acetonitrile, benzotriazole-5-carboxylic acid, 1H-benzotriazole-1-methanol and carboxybenzotriazole, substituted with amino groups, and mercapto group-containing triazole compounds such as 3-mercaptotriazole and 5-mercaptotriazole, substituted with amino groups.

Among these there are preferably included mercapto group-containing triazole compounds substituted with amino groups, from the viewpoint of further reducing development residue. A specific example is 3-amino-5-mercaptotriazole (trade name: AMT by BASF Corp.).

Tetrazole compounds with amino groups include compounds represented by the following formula (D-1).

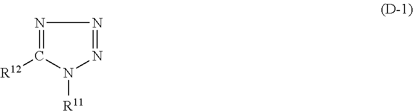

In formula (D-1), R¹¹ and R¹² each independently represent hydrogen, C1-20 alkyl, amino, mercapto or carboxymethyl, with at least one of R¹¹ and R¹² having an amino group.

Alkyl groups include methyl, ethyl, propyl and the like.

Preferred among tetrazole compounds represented by formula (D-1) are 5-amino-1H-tetrazole, 1-methyl-5-amino-tetrazole and 1-carboxymethyl-5-amino-tetrazole.

As component (D) there may also be used water-soluble salts of tetrazole compounds represented by formula (D-1). Specific examples include 1-methyl-5-amino-tetrazole salts with alkali metals such as sodium, potassium and lithium.

These tetrazole compounds and their water-soluble salts may be used alone, or two or more may be used in combination.

Of these, component (D) is most preferably 5-amino-1H-tetrazole or 1-methyl-5-mercapto-1H-tetrazole, from the viewpoint of obtaining minimal electrode corrosion, adhesiveness with metal electrodes, facilitated development and transparency.

Also, from the viewpoint of further improving the developability when the electrode surface to be provided with the protective coat has a metal such as copper, copper alloy or nickel alloy, the photosensitive resin composition particularly preferably further comprises a compound that is an amino group-containing tetrazole compound or a mercapto group-containing triazole compound that has been substituted with an amino group, among the compounds mentioned above. This can reduce development residue and facilitate formation of a protective coat with a satisfactory pattern. The reason for this is believed to be that suitable adhesiveness with the surface is exhibited.

Including an amino group-containing tetrazole compound or a mercapto group-containing triazole compound that has been substituted with an amino group will exhibit the effect described above, and therefore the photosensitive resin composition and photosensitive element of the invention will be suitable for formation of a protective coat for protection of an electrode in the frame region of a touch panel that has increased conductivity by formation of a metal layer such as copper.

The content of component (D) in the photosensitive resin composition of this embodiment is preferably 0.05 to 10.0 parts by mass, more preferably 0.1 to 2.0 parts by mass and even more preferably 0.2 to 1.0 part by mass with respect to 100 parts by mass as the total of component (A) and component (B).

If the content of component (D) is within this range it will be possible to minimize problems such as reduced developability and resolution, while obtaining a sufficient effect of inhibiting electrode corrosion and improving adhesiveness with metal electrodes.

Incidentally, when a protective coat is to be formed on sections of ITO electrodes of a touch panel, such as when a protective coat is to be formed on ITO electrodes in the frame region and sections of ITO electrodes on which a metal layer such as copper has been formed, without forming the protective coat on the sensing region, active light rays may be irradiated after forming a photosensitive layer over the entire panel, and development carried out to remove the undesired portions. In this case, the photosensitive layer must have sufficient adhesiveness for the electrodes to be protected, as well as satisfactory developability so that development residue is not generated at the undesired sections. From the viewpoint of both adhesiveness and developability for such cases, the photosensitive resin composition of this embodiment preferably comprises a phosphoric acid ester containing a photopolymerizable unsaturated bond (hereunder also referred to as component (E)).

The phosphoric acid ester containing a photopolymerizable unsaturated bond as component (E) is preferably a compound having the following structure, from the viewpoint of ensuring adequate rust resistance of the protective coat to be formed, while obtaining high levels of both adhesiveness for ITO electrodes and developability. This compound is available as a commercial product such as PM21 (product of Nippon Kayaku Co., Ltd.).

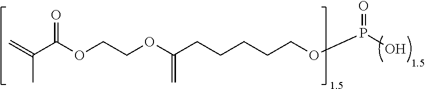

The phosphoric acid ester content is preferably adjusted so that the hydroxyl value of the photosensitive resin composition of this embodiment is no greater than 40 mgKOH/g.

The photosensitive resin composition of this embodiment may also contain, if necessary, a tackifier such as a silane coupling agent, or a leveling agent, plasticizer, filler, antifoaming agent, flame retardant, stabilizer, antioxidant, aromatic, thermal crosslinking agent, polymerization inhibitor or the like, at about 0.01 to 20 parts by mass each with respect to 100 parts by mass as the total of component (A) and component (B). They may be used alone or in combinations of two or more.

The minimum visible light transmittance of the photosensitive resin composition of this embodiment at 400 to 700 nm is preferably 90% or greater, more preferably 92% or greater and even more preferably 95% or greater.

The visible light transmittance of the photosensitive resin composition is determined in the following manner. First, a support film is coated with a coating solution containing the photosensitive resin composition, to a post-drying thickness of no greater than 10 μm, and it is dried to form a photosensitive resin composition layer. Next, it is laminated onto a glass panel using a laminator, with the photosensitive resin composition layer in contact. A measuring sample is thus obtained having a photosensitive resin composition layer and a support film laminated on a glass panel. The obtained measuring sample is then irradiated with ultraviolet rays to photocure the photosensitive resin composition layer, after which an ultraviolet and visible spectrophotometer is used to measure the transmittance in a measuring wavelength range of 400 to 700 nm.

If the transmittance is at least 90% in a wavelength range of 400 to 700 nm, which are light rays in the ordinary visible light wavelength range, for example, when a transparent electrode in the sensing region of a touch panel (touch sensor) is to be protected, or when the protective coat is visible from the edges of the sensing region after a metal layer (such as a copper layer formed on an ITO electrode) in the frame region of a touch panel (touch sensor) has been protected, it will be possible to satisfactorily minimize reduction in the image display quality, color shade and brightness in the sensing region.

The photosensitive resin composition of this embodiment may be used to form a photosensitive layer on a base material that has an electrode for a touch panel. For example, a coating solution that can be obtained by uniformly dissolving or dispersing the photosensitive resin composition in a solvent may be coated on a base material to form a coating film, and the solvent removed by drying to form a photosensitive layer.

The solvent used may be a ketone, aromatic hydrocarbon, alcohol, glycol ether, glycol alkyl ether, glycol alkyl ether acetate, ester, diethylene glycol, chloroform, methylene chloride or the like, from the viewpoint of the solubility of each component and ease of coating film formation. These solvents may be used alone, or a mixed solvent may be used, comprising two or more different solvents.

Preferred for use among these solvents are diethyleneglycol dimethyl ether, diethyleneglycol ethyl methyl ether, diethyleneglycol diethyl ether, propyleneglycol monomethyl ether, ethylene glycol monobutyl ether acetate, diethyleneglycol monoethyl ether acetate and propyleneglycol monomethyl ether acetate.

The photosensitive resin composition of this embodiment is preferably used to form a photosensitive film, as for a photosensitive element. By laminating a photosensitive film on a base material with an electrode for a touch panel, it is possible to significantly contribute to shortening of the production process and reduction of costs, by allowing a roll-to-roll process to be easily accomplished and by shortening the solvent drying step, for example.

The photosensitive layer 20 of the photosensitive element 1 can be formed by preparing a coating solution containing the photosensitive resin composition of this embodiment, and coating and drying it on a support film 10. The coating solution can be obtained by uniformly dissolving or dispersing each of the components used to form the photosensitive resin composition of this embodiment, in a solvent.

There are no particular restrictions on the solvent, and a known one may be used such as acetone, methyl ethyl ketone, methyl isobutyl ketone, toluene, methanol, ethanol, propanol, butanol, methylene glycol, ethylene glycol, propylene glycol, ethylene glycol monomethyl ether, ethylene glycol monoethyl ether, diethylene glycol dimethyl ether, diethylene glycol ethyl methyl ether, diethylene glycol diethyl ether, propyleneglycol monomethyl ether, ethylene glycol monobutyl ether acetate, diethylene glycol monoethyl ether acetate, propyleneglycol monomethyl ether acetate, chloroform or methylene chloride, for example. These solvents may be used alone, or a mixed solvent may be used, comprising two or more different solvents.

The coating method may be, for example, doctor blade coating, Meyer bar coating, roll coating, screen coating, spinner coating, ink-jet coating, spray coating, dip coating, gravure coating, curtain coating or die coating.

There are no particular restrictions on the drying conditions, but the drying temperature is preferably 60° C. to 130° C. and the drying time is preferably 30 seconds to 30 minutes.

The thickness of the photosensitive layer 20 is preferably 1 μm to 10 μm, more preferably 1 μm to 9 μm, even more preferably 1 μm to 8 μm, yet more preferably 2 μm to 8 μm and most preferably 3 μm to 8 μm, as the post-drying thickness, in order to exhibit an adequate effect for electrode protection and to reduce to a minimum any level differences on the touch panel (touch sensor) surface that are produced by partial electrode-protecting coat formation.

The minimum visible light transmittance of the photosensitive layer 20 for the photosensitive element 1 of this embodiment is preferably 90% or greater, more preferably 92% or greater and even more preferably 95% or greater.

The viscosity of the photosensitive layer 20 at 30° C. is preferably 15 to 100 mPa·s, more preferably 20 to 90 mPa·s and even more preferably 25 to 80 mPa·s, from the viewpoint of preventing, for a period of one month or longer, exudation of the photosensitive resin composition from the edges of the photosensitive element when the photosensitive element has been taken up into a roll, and from the viewpoint of preventing exposure defects and development residue during irradiation of active light rays, caused by adhesion of fragments of the photosensitive resin composition on the substrate when the photosensitive element is cut.

The viscosity is the value obtained by forming a circular film with a diameter of 7 mm and a thickness of 2 mm from the photosensitive resin composition as a measuring sample, measuring the rate of change in thickness upon adding a load of 1.96×10⁻² N at 30° C. and 80° C. in the thickness direction of the sample, and calculating the viscosity from the change in thickness, assuming a Newtonian fluid.

The protective film 30 (cover film) may be, for example, a film composed of polyethylene, polypropylene, polyethylene terephthalate, polycarbonate, polyethylene-vinyl acetate copolymer or polyethylene-vinyl acetate copolymer, or a laminated film of polyethylene-vinyl acetate copolymer and polyethylene.

The thickness of the protective film 30 is preferably about 5 to 100 μm, but from the viewpoint of curled storage as a roll, it is preferably no greater than 70 μm, more preferably no greater than 60 μm, even more preferably no greater than 50 μm and most preferably no greater than 40 μm.

The photosensitive element 1 may be used in curled storage as a roll.

According to the invention, a coating solution containing the photosensitive resin composition of this embodiment and a solvent is coated onto a base material having an electrode for a touch panel, and dried to form a photosensitive layer composed of the photosensitive resin composition. Even with this type of use, the photosensitive layer preferably satisfies the same conditions of film thickness and visible light transmittance as for the photosensitive layer 20 of the photosensitive element 1.

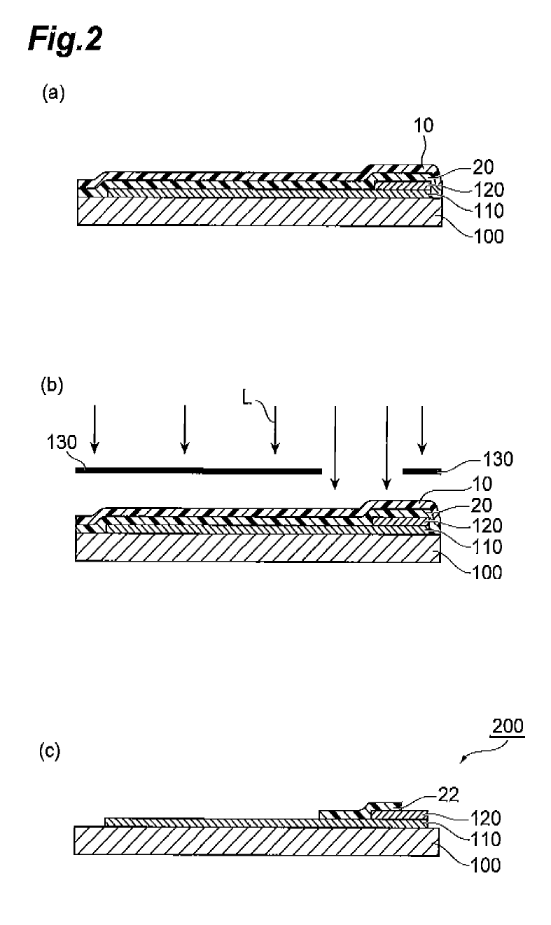

A method for forming a protective coat on an electrode for a touch panel according to the invention will now be described. FIG. 2 is a schematic cross-sectional view for illustration of an embodiment of a method for forming a protective coat on an electrode for a touch panel according to the invention.

The method for forming a protective coat 22 on an electrode for a touch panel according to this embodiment comprises a first step in which a photosensitive layer 20 comprising a photosensitive resin composition according to the invention is formed on a base material 100 having electrodes for a touch panel 110 and 120, a second step in which prescribed sections of the photosensitive layer 20 are cured by irradiation with active light rays, and a third step in which the sections other than the prescribed sections of the photosensitive layer 20 are removed after the irradiation with active light rays, to form a protective coat 22 comprising the cured sections of the photosensitive layer covering all or a portion of the electrodes. A protective coat-covered touch panel (touch, sensor) 200 is thus obtained as a touch input sheet.

The base material 100 to be used for this embodiment may be a substrate such as a glass plate, plastic sheet or ceramic sheet commonly used for touch panels (touch sensors). An electrode for a touch panel on which the protective coat is to be formed is provided on the substrate. The electrode may be an ITO, Cu, Al or Mo electrode, or TFT. An insulating layer may also be provided on the substrate between the substrate and the electrode.

The base material 100 having electrodes for a touch panel 110 and 120 shown in FIG. 2 can be obtained by the following procedure, for example. After forming a metal film by sputtering in the order ITO, Cu on a base material such as a PET film, a photosensitive film for etching is attached onto the metal film, a desired resist pattern is formed, and the unwanted Cu is removed with an etching solution such as an iron chloride aqueous solution, after which the resist pattern is peeled off.

In the first step of this embodiment, the protective film 30 of the photosensitive element 1 of this embodiment is removed and then the photosensitive layer 20 is transferred onto the surface of the base material 100 on which the electrodes for a touch panel 110 and 120 are formed, by contact bonding while heating the photosensitive element 1, to accomplish lamination (see FIG. 2(a)).

The contact bonding means may be a contact bonding roll. The contact bonding roll may be one provided with heating means to allow thermocompression bonding.

The heating temperature for thermocompression bonding is preferably 10° C. to 180° C., more preferably 20° C. to 160° C. and even more preferably 30° C. to 150° C. so that the constituent components of the photosensitive layer 20 will be more resistant to thermosetting or thermal decomposition, while ensuring sufficient adhesiveness between the photosensitive layer 20 and the base material 100 and sufficient adhesiveness between the photosensitive layer 20 and the electrodes for a touch panel 110 and 120.

Also, the contact bonding pressure during thermocompression bonding is preferably 50 to 1×10⁵ N/m, more preferably 2.5×10² to 5×10⁴ N/m even more preferably 5×10² to 4×10⁴ N/m as linear pressure, from the viewpoint of minimizing deformation of the base material 100 while ensuring sufficient adhesiveness between the photosensitive layer 20 and the base material 100.

If the photosensitive element 1 is heated in this manner it will not be necessary to perform preheating treatment of the base material 100, although preheating treatment of the base material 100 is preferred from the viewpoint of further increasing adhesiveness between the photosensitive layer 20 and the base material 100. The preheating temperature is preferably 30° C. to 180° C.

For this embodiment, instead of using a photosensitive element 1, a coating solution containing the photosensitive resin composition of this embodiment and a solvent may be prepared and coated and dried onto the surface of the base material 100 on which the electrodes for a touch panel 110 and 120 have been formed, to form a photosensitive layer 20.

In the second step of this embodiment, active light rays L are irradiated in a pattern on prescribed sections of the photosensitive layer 20, through a photomask 130 (see FIG. 2(b)).

For irradiation of the active light rays, if the support film 10 on the photosensitive layer 20 is transparent it will be possible to irradiate the active light rays directly, but if it is opaque the active light rays are irradiated after removing it. From the viewpoint of protecting the photosensitive layer 20, preferably a transparent polymer film is used as the support film 10 and the polymer film is left on it, with the active light irradiation being performed through it.

The light source used for irradiation of the active light rays L may be a known active light source such as a carbon arc lamp, ultra-high-pressure mercury lamp, high-pressure mercury lamp or xenon lamp, with no particular restrictions so long as the ultraviolet rays can be effectively emitted.

The exposure dose for the active light rays L will usually be 1×10² to 1×10⁴ J/m², and the irradiation may also be accompanied by heating. If the active light ray exposure dose is less than 1×10² J/m² the photocuring effect will tend to be inadequate, and if it is greater than 1×10⁴ J/m² the photosensitive layer 20 will tend to undergo discoloration.

In the third step of this embodiment, the photosensitive layer 20 that has been irradiated with active light rays is developed with a developing solution to remove the sections that have not been exposed to active light rays (i.e. the sections other than the prescribed sections of the photosensitive layer), to form a protective coat 22 composed of the cured sections of the photosensitive layer of the invention covering all or a portion of the electrode (see FIG. 2(c)). The protective coat 22 formed may have a prescribed pattern.

When the support film 10 is layered on the photosensitive layer 20 after irradiation with active light rays, it is first removed, and then development is carried out with a developing solution for removal of the sections that have not been exposed to the active light rays.

The developing method preferably accomplishes development by a known method such as spraying, showering, reciprocal dipping, brushing or scrapping using a known developing solution such as an aqueous alkali solution, aqueous developing solution or organic solvent, and removal of the unwanted sections, and the use of an aqueous alkali solution is preferred from the viewpoint of the environment and safety.

Among aqueous alkali solutions it is preferred to use a sodium carbonate aqueous solution. For example, a dilute sodium carbonate solution (0.5 to 5 mass % aqueous solution) at 20° C. to 50° C. is preferably used.

The developing temperature and time can be adjusted to match the developability of the photosensitive resin composition for this embodiment.

The aqueous alkali solution may also contain added surfactants, antifoaming agents, and small amounts of organic solvents to accelerate development.

After development, the base of the aqueous alkali solution remaining on the photosensitive layer 20 after photocuring may be subjected to acid treatment (neutralizing treatment) by a known method such as spraying, reciprocal dipping, brushing, scrapping or the like using an organic acid or inorganic acid, or an aqueous solution of such acids.

A step of rinsing may also be carried out after acid treatment (neutralizing treatment).

Following development, the cured film may be further cured by irradiation with active light rays (for example, 5×10³ to 2×10⁴ J/m²), if necessary. The photosensitive resin composition of this embodiment exhibits excellent adhesiveness for metals even without a heating step after development, but if necessary it may be subjected to heat treatment (80° C. to 250° C.) instead of irradiation with active light rays or in combination with irradiation with active light rays, after development.

Thus, the photosensitive resin composition and photosensitive element of this embodiment can be suitably used for formation of a protective coat on an electrode for a touch panel. For this use of the photosensitive resin composition, a coating solution in admixture with a solvent may be used to form the protective coat.

The invention further provides a material for forming a protective coat on an electrode for a touch panel, comprising a photosensitive resin composition according to the invention. The material for forming a protective coat on an electrode for a touch panel may comprise a photosensitive resin composition of the embodiment described above, and it is preferably a coating solution further containing the solvent mentioned above.

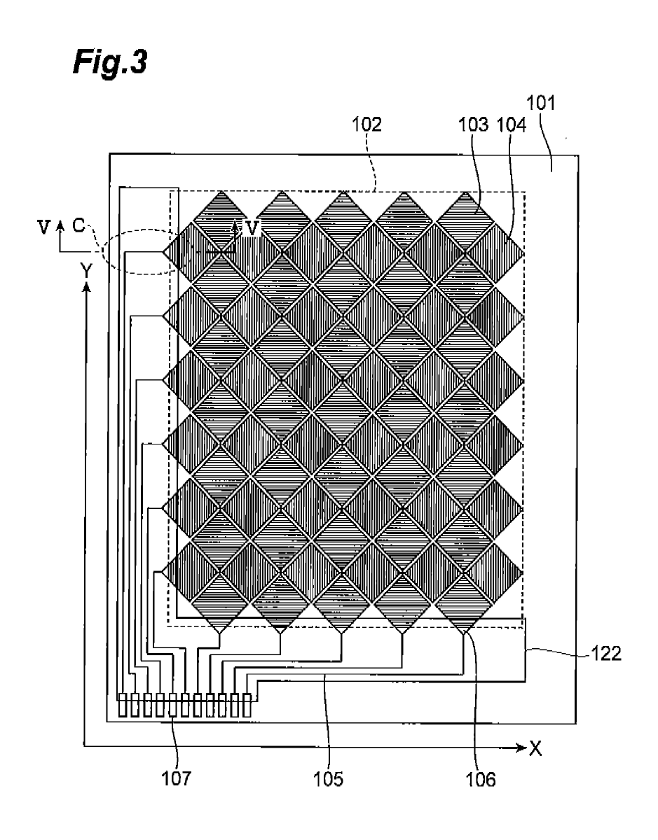

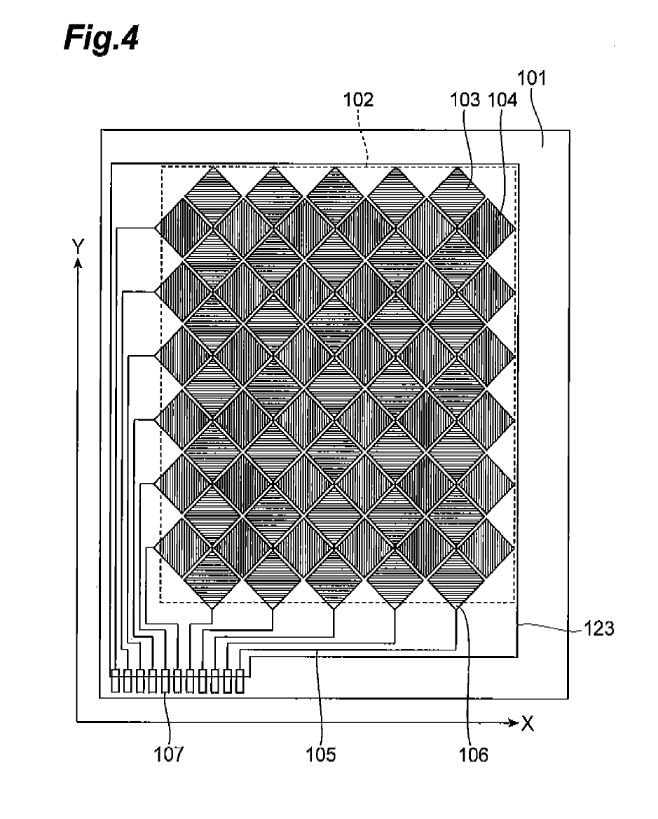

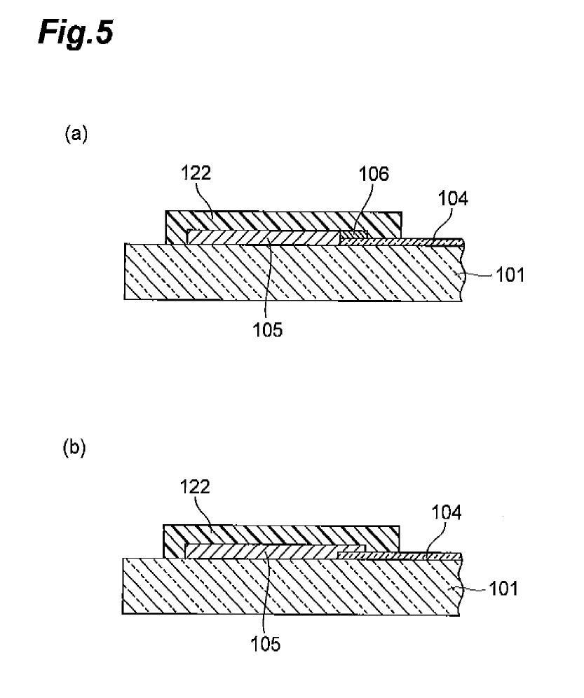

An example of a part using a protective coat of the invention will now be described with reference to FIG. 3, FIG. 4 and FIG. 5. FIG. 3 is a schematic top view showing an example of an electrostatic capacitive touch panel. The touch panel illustrated in FIG. 3 has a touch screen 102 for detection of touch location coordinates on one side of a transparent substrate 101, and provided on the transparent substrate 101 are transparent electrodes 103 and transparent electrodes 104 for detection of changes in electrostatic capacity in this region. The transparent electrodes 103 and transparent electrodes 104 detect the X-position coordinate and Y-position coordinate, respectively, of the touch location.

On the transparent substrate 101 there are provided lead wirings 105 to transmit touch location detection signals from the transparent electrodes 103 and transparent electrodes 104 to an external circuit. Also, the lead wirings 105 and the transparent electrodes 103 and transparent electrodes 104 are connected by connecting electrodes 106 provided on the transparent electrodes 103 and transparent electrodes 104. On the side opposite the connecting sections between the lead wirings 105 and the transparent electrodes 103 and transparent electrodes 104, there are provided connecting terminals 107 with an external circuit. The photosensitive resin composition of this embodiment can be suitably used to form a protective coat 122 for the lead wirings 105, connecting electrodes 106 and connecting terminals 107. This allows simultaneous protection of the electrodes in the sensing region (touch screen 102). In FIG. 3, the protective coat 122 protects the lead wirings 105, connecting electrodes 106, some of the electrodes in the sensing region and some of the connecting terminals 107, but the location where the protective coat is provided may be changed as appropriate. For example, as shown in FIG. 4, the protective coat 123 may be provided protecting the entire touch screen 102.

The cross-sectional structure of the connecting section between the transparent electrodes and lead wirings in the touch panel shown in FIG. 3 will now be explained with reference to FIG. 5. FIG. 5 is a partial cross-sectional view of section C in FIG. 3 along line V-V, showing a connecting section between a transparent electrode 104 and a lead wiring 105. As shown in FIG. 5(a), the transparent electrode 104 and the lead wiring 105 are electrically connected via a connecting electrode 106. Also as shown in FIG. 5(a), part of the transparent electrode 104, and all of the lead wiring 105 and connecting electrode 106, are covered by the protective coat 122. Likewise, the transparent electrode 103 and the lead wiring 105 are electrically connected via a connecting electrode 106. The photosensitive resin composition and photosensitive element of this embodiment can be suitably used for formation of a protective coat in the connection structure described above.

A method for manufacturing a touch panel according to this embodiment will now be explained. First, transparent electrodes (X-position coordinate) 103 are formed on a transparent electrode 101 provided on a base material 100. Next, transparent electrodes (Y-position coordinate) 104 are formed. Formation of the transparent electrodes 103 and transparent electrodes 104 may be accomplished by a method of etching a transparent electrode layer formed on the base material 100.

Next, on the surface of the transparent substrate 101 there are formed lead wirings 105 for connection to an external circuit and connecting electrodes 106 connecting the lead wirings with the transparent electrodes 103 and transparent electrodes 104. The lead wirings 105 and connecting electrodes 106 may be formed after formation of the transparent electrodes 103 and transparent electrodes 104, or they may be formed simultaneously during formation of the respective transparent electrodes. Formation of the lead wirings 105 and connecting electrodes 106 may involve metal sputtering followed by etching or the like. The lead wirings 105 can be formed simultaneously with formation of the connecting electrodes 106, for example, using a conductive paste material containing silver flakes, by screen printing or the like. Next, connecting terminals 107 are formed for connection between the lead wirings 105 and an external circuit.

In order to cover the transparent electrodes 103 and transparent electrodes 104, the lead wirings 105, the connecting electrodes 106 and the connecting terminals 107 formed by this step, the photosensitive element 1 of this embodiment is contact bonded and a photosensitive layer 20 is provided over the electrodes. Next, the transferred photosensitive layer 20 is exposed to active light rays L in a pattern through a photomask having a prescribed shape. After irradiation of the active light rays L, development is performed and all but the prescribed sections of the photosensitive layer 20 are removed, to form a protective coat 122 composed of the cured sections of the photosensitive layer 20. It is possible in this manner to produce a touch panel provided with a protective coat 122.

### EXAMPLES

The present invention will now be explained in greater detail by examples. However, the present invention is not limited to the examples described below.

### Preparation of Binder Polymer Solution (A1)

In a flask equipped with a stirrer, a reflux condenser, an inert gas inlet and a thermometer there was charged component (1) listed in Table 1, the temperature was raised to 80° C. under a nitrogen gas atmosphere, and component (2) listed in Table 1 was added dropwise uniformly over a period of 4 hours while maintaining a reaction temperature of 80° C.±2° C. After dropwise addition of component (2), stirring was continued at 80° C.±2° C. for 6 hours, to obtain a binder polymer solution with a weight-average molecular weight of approximately 65,000, a hydroxyl value of 2 mgKOH/g and an acid value of 78 mgKOH/g (45 mass % solid portion) (A1).

### Preparation of Binder Polymer Solutions (A2) to (A4) and (A6) to (A8)

Binder polymer solutions (A2) to (A4) and (A6) to (A8) were obtained in the same manner as (A1) above, with the compositions listed in Table 1 and Table 2. The results are shown in Table 1 and Table 2.

### Preparation of Binder Polymer Solution (A5)

The component MIS-115 (a propyleneglycol monomethyl ether acetate/methyl lactate solution of a compound obtained by reacting 18.6 g of 2-isocyanatoethyl methacrylate with a copolymer obtained by reacting 12 g of methacrylic acid, 11.1 g of N-cyclohexylmaleimide, 27.2 g of dicyclopentanyl methacrylate and 31.1 g of 2-hydroxyethyl methacrylate) was prepared and used as binder polymer solution (A5). The weight-average molecular weight was approximately 26,000, the hydroxyl value was 80.2 mgKOH/g and the acid value was 55 mgKOH/g.

TABLE 1

| | | Content (parts by mass) | | | | |
|---|---|---|---|---|---|---|
| | | (A1) | (A2) | (A3) | (A4) | (A5) |
| (1) | Propyleneglycol | 62 | 62 | 62 | 62 | *1 |
| | monomethylether | | | | | |
| | Toluene | 62 | 62 | 62 | 63 | |
| | Propyleneglycol | — | — | — | — | |
| | monomethylether acetate | | | | | |
| | Ethyl lactate | — | — | — | — | |
| (2) | Methacrylic acid | 12 | 17.5 | 12 | 12 | |
| | Methyl methacrylate | 58 | 52.5 | 48 | 28 | |
| | Ethyl acrylate | 30 | 30 | 30 | 30 | |
| | Butyl acrylate | — | — | — | — | |
| | Butyl methacrylate | — | — | — | — | |
| | 2-Hydroxyethyl | — | — | 10 | 30 | |
| | methacrylate | | | | | |
| | N-Cyclohexyl maleimide | — | — | — | — | |
| | Dicyclopentanyl | — | — | — | — | |
| | methacrylate | | | | | |
| | 2,2′-Azobis (isobutyronitrile) | 1.5 | 1.2 | 1.5 | 1.5 | |

| | | | | | |
|---|---|---|---|---|---|
| Weight-average molecular weight | 65,000 | 80,000 | 45,000 | 47,000 | 26,000 |
| Hydroxyl value (mgKOH/g) | 2 | 1 | 43 | 129 | 80.2 |
| Acid value (mgKOH/g) | 78 | 115 | 78 | 78 | 55 |
| Tg (° C.) | 60 | 65 | 80 | 72 | 59 |

*1: MIS-115.

TABLE 2

| | | Content (parts by mass) | | |
|---|---|---|---|---|
| | | (A6) | (A7) | (A8) |
| (1) | Propyleneglycol | 62 | 62 | 62 |
| | monomethylether | | | |
| | Toluene | 62 | 62 | 62 |
| | Propyleneglycol | — | — | — |
| | monomethylether acetate | | | |
| | Ethyl lactate | — | — | — |
| (2) | Methacrylic acid | 24 | 30 | 24 |
| | Methyl methacrylate | 43.5 | 35 | 46 |
| | Ethyl acrylate | — | — | 30 |
| | Butyl acrylate | 15 | — | — |
| | Butyl methacrylate | 17.5 | 35 | — |
| | 2-Hydroxyethyl | — | — | — |
| | methacrylate | | | |
| | N-Cyclohexyl maleimide | — | — | — |
| | Dicyclopentanyl | — | — | — |
| | methacrylate | | | |
| | 2,2′-Azobis (isobutyronitrile) | 1.5 | 1.5 | 1.5 |

| | | | |
|---|---|---|---|
| Weight-average molecular weight | 35,000 | 45,000 | 45,000 |
| Hydroxyl value (mgKOH/g) | 1 | 2 | 1 |
| Acid value (mgKOH/g) | 156 | 195 | 155 |
| Tg (° C.) | 65 | 85 | 71 |

The weight-average molecular weight (Mw) was measured by gel permeation chromatography (GPC), and calculation was performed using a standard polystyrene calibration curve. The GPC conditions were as follows.

GPC conditions
Pump: Hitachi L-6000 (product name of Hitachi, Ltd.),
Column: Gelpack GL-R420, Gelpack GL-R430, Gelpack GL-11440 (all product names of Hitachi Chemical Co., Ltd.).
Eluent: tetrahydrofuran
Measuring temperature: 40° C.
Flow rate: 2.05 mL/min
Detector: Hitachi L-3300 RI (product name of Hitachi, Ltd.).

### [Acid Value Measuring Method]

The acid value was measured in the following manner. First, a binder polymer solution was heated at 130° C. for 1 hour to remove the volatile components and obtain a solid portion. After then precisely weighing out 1 g of polymer whose acid value was to be measured, the weighed out polymer was placed in an Erlenmeyer flask and 30 g of acetone was added to the polymer to form a homogeneous solution. Next, an appropriate amount of phenolphthalein was added to the solution as an indicator, and a 0.1N KOH aqueous solution was used for titration. The acid value was then calculated by the following formula.

Acid value=0.1×Vf×56.1/(Wp×I)

In the formula, Vf represents the titer (mL) of the KOH aqueous solution, Wp represents the weight (g) of the measured resin solution, and I represents the ratio (mass %) of nonvolatile components in the measured resin solution.

### [Hydroxyl Value Measuring Method]

The hydroxyl value was measured in the following manner. First, a binder polymer solution was heated at 130° C. for 1 hour to remove the volatile components and obtain a solid portion. Also, after precisely weighing out 1 g of the polymer whose hydroxyl value was to be measured, the weighed out photosensitive resin composition was placed in an Erlenmeyer flask, 10 mL of a 10 mass % acetic anhydride/pyridine solution was added to uniform dissolution, and the mixture was heated at 100° C. for 1 hour. After heating, 10 mL of water and 10 mL of pyridine were added and the mixture was heated at 100° C. for 10 minutes, and then an automatic titrator (“COM-1700” by Hiranuma Sangyo Corp.) was used for neutralization titration with a 0.5 mol/L ethanol solution of potassium hydroxide. The hydroxyl value was calculated by the following formula.

Hydroxyl value=(A−B)×f×28.05/sample(g)+acid value

In the formula, A represents the amount (mL) of 0.5 mol/L potassium hydroxide ethanol solution used for the blank test, B represents the amount (mL) of 0.5 mol/L potassium hydroxide ethanol solution used for titration, and f represents the factor.

The hydroxyl values of the photopolymerizable compounds used in the procedure described below were measured by the same method as above.

### Example 1

### Preparation of Coating Solution Containing Photosensitive Resin Composition

The materials listed in Table 3 were mixed for 15 minutes using a stirrer, to prepare a coating solution containing a solvent and the photosensitive resin composition of Example 1.

TABLE 3

| | | Example | | | | | | | |
|---|---|---|---|---|---|---|---|---|---|
| | | 1 | 2 | 3 | 4 | 5 | 6 | 7 | 8 |
| Component | (A1) | 60*² | — | — | — | 60*² | 60*² | 60*² | — |
| (A) | (A2) | — | — | — | — | — | — | — | — |
| | (A3) | — | 60*² | 60*² | 60*² | — | | — | 60*² |
| | (A4) | — | — | — | — | — | — | — | — |
| | (A5) | — | — | — | — | — | — | — | — |
| Component | DPHA | 40 | 40 | — | — | — | — | — | — |
| (B) | TMPTA | — | — | 40 | 40 | — | — | — | — |
| | A-9550 | — | — | — | — | 40 | — | — | 40 |
| | A-9570 | — | — | — | — | — | 40 | 40 | — |
| | PET-30 | — | — | — | — | — | — | — | — |
| | A-TMM-3 | — | — | — | — | — | — | — | — |
| | A-TMM-3LM-N | — | — | — | — | — | — | — | — |
| Component | IRGACURE | 5 | 5 | 5 | 5 | 5 | 5 | 5 | 5 |
| (C) | OXE 01 | | | | | | | | |
| Component | AMT | 0.5 | 0.5 | 0.5 | 0.5 | 0.5 | — | — | — |
| (D) | HAT | — | — | — | — | — | 0.5 | 0.5 | 0.5 |
| Component | PM-21 | — | — | — | 0.2 | — | — | 0.2 | — |
| (E) | | | | | | | | | |
| Other | Antage W-500 | 0.1 | 0.1 | 0.1 | 0.1 | 0.1 | 0.1 | 0.1 | 0.1 |
| | Methyl ethyl ketone | 50 | 50 | 50 | 50 | 50 | 50 | 50 | 50 |

| | | | | | | | | |
|---|---|---|---|---|---|---|---|---|
| Hydroxyl value of photosensitive resin | 16.3 | 39.6 | 24.4 | 24.4 | 16.3 | 27.7 | 27.6 | 39.6 |
| composition (mgKOH/g) | | | | | | | | |

*²Indicates parts by mass of binder polymer after removal of solvent.

### [Measurement of Photosensitive Resin Composition Hydroxyl Value]

The prepared coating solution was heated at 130° C. for 1 hour to remove the solvent, and then 1 g was precisely weighed out. The weighed out photosensitive resin composition was placed in an Erlenmeyer flask, 10 mL of a 10 mass % acetic anhydride/pyridine solution was added, and the mixture was uniformly dissolved and heated at 100° C. for 1 hour. After heating, 10 mL of water and 10 mL of pyridine were added and the mixture was heated at 100° C. for 10 minutes, and then an automatic titrator (“COM-1700” by Hiranuma Sangyo Corp.) was used for neutralization titration with a 0.5 mol/L potassium hydroxide ethanol solution, to measure the hydroxyl value,

### [Fabrication of Photosensitive Element]

Using a polyethylene terephthalate film with a thickness of 50 μm as the support film, the coating solution containing the photosensitive resin composition and solvent prepared above was uniformly coated onto the support film with a comma coater, and dried for 3 minutes at 100° C. with a hot air convection drier to remove the solvent, thereby forming a photosensitive layer comprising the photosensitive resin composition (photosensitive resin composition layer). The thickness of the obtained photosensitive layer was 5 μm.

Next, a 25 μm-thick polyethylene film was attached as a cover film on the obtained photosensitive layer, to fabricate a photosensitive element for formation of a protective coat.

### [Measurement of Protective Coat Transmittance]

While releasing the polyethylene film of the obtained photosensitive element, a laminator (trade name HLM-3000 by Hitachi Chemical Co., Ltd.) was used for lamination on a 1 mm-thick glass panel with the photosensitive layer in contact therewith, under conditions with a roll temperature of 120° C., a substrate feed rate of 1 m/min and a contact bonding pressure (cylinder pressure) of 4×10⁵ Pa (because a substrate with a thickness of 1 mm and 10 cm length×10 cm width was used, the linear pressure at this time was 9.8×10³ N/m), to form a stack with the photosensitive layer and support film laminated on the glass panel.

Next, a parallel ray exposure device (EXM1201 by Ore Manufacturing Co., Ltd.) was used to expose the photosensitive layer of the obtained stack to ultraviolet rays with an exposure dose of 5×10² J/m² (measured value for i-rays (wavelength of 365 nm)) from the photosensitive layer side, and then the support film was removed to obtain a transmittance measuring sample having a protective coat composed of a cured photosensitive layer with a thickness of 5.0 μm.

Next, the visible light transmittance of the obtained sample at a measuring wavelength range of 400 to 700 nm was measured using an U-3310 spectrophotometer (product of Hitachi, Ltd.). The minimum transmittance of the obtained protective coat at 400 to 700 nm was 94%, indicating that satisfactory transmittance had been ensured.

### [Protective Coat Salt Spray Test (Synthetic Sweat Resistance Evaluation Test)]

While releasing the polyethylene film of the obtained photosensitive element, a laminator (trade name HLM-3000 by Hitachi Chemical Co., Ltd.) was used for lamination on a sputtered copper-covered polyimide film (product of Toray Advanced Film Co., Ltd.) with the photosensitive layer in contact therewith, under conditions with a roll temperature of 120° C., a substrate feed rate of 1 m/min and a contact bonding pressure (cylinder pressure) of 4×10⁵ Pa (because a substrate with a thickness of 1 mm and 10 cm length×10 cm width was used, the linear pressure at this time was 9.8×10³ N/m), to form a stack with the photosensitive layer and support film laminated on the sputtered copper.

Next, a parallel ray exposure device (EXM1201 by Ore Manufacturing Co., Ltd.) was used to expose the photosensitive layer of the obtained stack to ultraviolet rays with an exposure dose of 5×10² J/m² (measured value for i-rays (wavelength of 365 nm)) from the photosensitive side, and then the support film was removed and ultraviolet rays were further irradiated at an exposure dose of 1×10⁴ J/m² (measured value for i-rays (wavelength of 365 nm)) from the photosensitive layer side, to obtain a synthetic sweat resistance evaluation sample having a protective coat composed of a cured photosensitive layer with a thickness of 5.0 μm.

Next, using a salt water spray tester (STP-90V2 by Suga Test Instruments Co., Ltd.) according to JIS (Z 2371), the sample was mounted in the test chamber and salt water (pH=6.7) at a concentration of 50 g/L was sprayed for 48 hours at a test chamber temperature of 35° C. and a spraying volume of 1.5 mL/h. Upon completion of spraying, the salt water was wiped off and the surface condition of the evaluation sample was observed for evaluation on the following scale.

A: Absolutely no change in protective coat surface.
B: Very slight traces on protective coat surface, but no change in copper.
C: Traces on protective coat surface, but no change in copper.
D: Traces on protective coat surface, and discoloration of copper.

Based on observation of the surface condition of the evaluation sample, an evaluation of “B” was assigned, i.e. very slight traces on the protective coat surface and no change in copper.

### [Development Residue Test of Photosensitive Layer]

While releasing the polyethylene film as the cover film of the obtained photosensitive element, a laminator (trade name HLM-3000 by Hitachi Chemical Co., Ltd.) was used for lamination on a sputtered copper-covered polyimide film (product of Toray Advanced Film Co., Ltd.) with the photosensitive layer in contact therewith, under conditions with a roll temperature of 120° C., a substrate feed rate of 1 m/min and a contact bonding pressure (cylinder pressure) of 4×10⁵ Pa (because a substrate with a thickness of 1 mm and 10 cm length×10 cm width was used, the linear pressure at this time was 9.8×10³ N/m), to form a stack with the photosensitive layer and support film laminated on the sputtered copper.

After forming the stack and storing it for 24 hours under conditions with a temperature of 23° C. and a humidity of 60%, a photomask was set on the support film, the photomask having lines/spaces of 300 μm/300 μm, with alternate patterning of active light ray transparent sections and active light ray shielding sections, and a parallel ray exposure device (EXM1201 by Ore Manufacturing Co., Ltd.) was used for image irradiation of ultraviolet rays at an exposure dose of 5×10² J/m² (measured value for i-rays (wavelength of 365 nm)) from the direction normal to the photomask.

Next, the support film laminated on the photosensitive layer was removed and 1.0 mass % aqueous sodium carbonate was used for spray development at 30° C. for 40 seconds, to selectively remove the photosensitive layer and form a protective coat pattern. The base material surface condition was observed with a microscope at the sections of the obtained protective coat pattern-formed substrate where the photosensitive layer had been selectively removed, and the development residue was evaluated on the following scale.

A: Absolutely no change in base material surface.
B: Slight discoloration of copper on, base material surface, but no development residue.
C: Slight discoloration of copper on base material surface, and slight generation of development residue.
D: Generation of development residue.

Based on observation of the surface condition of the evaluation sample, an evaluation of “B” was assigned, i.e. absolutely no change in the base material surface.

### [Crosscut Adhesiveness Test of Protective Coat]

While releasing the polyethylene film as the cover film of the obtained photosensitive element, a laminator (trade name HLM-3000 by Hitachi Chemical Co., Ltd.) was used for lamination on a sputtered copper-covered polyimide film (product of Toray Advanced Film Co., Ltd.) with the photosensitive layer in contact therewith, under conditions with a roll temperature of 120° C., a substrate feed rate of 1 m/min and a contact bonding pressure (cylinder pressure) of 4×10⁵ Pa (because a substrate with a thickness of 1 mm and 10 cm length×10 cm width was used, the linear pressure at this time was 9.8×10³ N/m), to form a stack with the photosensitive layer and support film laminated on the sputtered copper.

Next, a parallel ray exposure device (EXM1201 by Ore Manufacturing Co., Ltd.) was used to expose the photosensitive layer of the obtained stack to ultraviolet rays with an exposure dose of 5×10² J/m² (measured value for i-rays (wavelength of 365 nm)) from the photosensitive layer side, and then the support film was removed and ultraviolet rays were further irradiated at an exposure dose of 1×10⁴ J/m² (measured value for i-rays (wavelength of 365 nm)) from the photosensitive layer side, to obtain a crosscut adhesiveness test sample having a protective coat composed of a cured photosensitive layer with a thickness of 5.0 μm.

Next, a 100-unit cross-cut test was conducted according to JIS (K5400). A cutter knife was used to form 1×1 mm square grid notches on the test surface, Mending Tape #810 (product of 3M Co.) was firmly contact bonded onto the grid section and the tape edge was slowly peeled off at an angle of 0°, after which the state of the grid was observed and the crosscut adhesiveness was evaluated on the following scale.

A: Bonding on essentially 100% of total area,
B: Bonding remaining on 95% or greater and less than 100% of total area
B-C: Bonding remaining on 85% or greater and less than 95% of total area.
C: Bonding remaining on 65% or greater and less than 85% of total area.
C-D: Bonding remaining on 35% or greater and less than 65% of total area.
D: Bonding remaining on 0% or greater and less than 35% of total area.

Upon observing the state of the grid of the evaluation sample, an evaluation of “B” was assigned, i.e. a state with bonding remaining on at least 95% of the total area of the sputtered copper.

### Examples 2 to 20 and Comparative Examples 1 to 12

A photosensitive element was fabricated in the same manner as Example 1, except for using the photosensitive resin compositions listed in Tables 3 to 7 (the numerical units in the tables are parts by mass), and transmittance measurement, salt water spray testing, development residue testing and crosscut adhesiveness testing were carried out. As shown in Tables 8 to 12, all of the examples had satisfactory results for transmittance measurement, salt water spray resistance evaluation and crosscut adhesiveness.

TABLE 4

| | | Example | | | | | | | |
|---|---|---|---|---|---|---|---|---|---|
| | | 9 | 10 | 11 | 12 | 13 | 14 | 15 | 16 |
| Component | (A1) | 55*² | 55*² | 55*² | — | — | — | 55*² | 55*² |
| (A) | (A2) | — | — | — | 55*² | 55*² | 55*² | — | — |
| | (A6) | — | — | — | — | — | — | — | — |
| | (A7) | — | — | — | — | — | — | — | — |
| | (A8) | — | — | — | — | — | — | — | — |
| Component | DPHA | — | — | — | 45 | 45 | 45 | 45 | — |
| (B) | TMPTA | — | — | — | — | — | — | — | 45 |
| | A-TMMT | 45 | 45 | — | — | — | — | — | — |
| | RP-1040 | — | — | 45 | — | — | — | — | — |
| | BPE-500 | — | — | — | — | — | — | — | — |
| Component | IRGACURE | 3 | 5 | 3 | 3 | 3 | 3 | 3 | 3 |
| (C) | OXE 01 | | | | | | | | |
| | LUCIRIN TPO | — | — | — | — | — | — | — | — |
| Component | 1HT | — | — | 0.5 | — | — | — | — | — |
| (D) | MMT | — | — | — | — | — | — | — | — |
| | HAT | — | — | — | — | 0.5 | — | — | — |
| | 3MT | — | — | — | — | — | 0.5 | — | — |
| | ATT | — | — | — | — | — | — | 0.5 | — |
| | AMT | — | — | — | — | — | — | — | 0.5 |
| Other | Antage W-500 | 0.1 | 0.1 | 0.1 | 0.1 | 0.1 | 0.1 | 0.1 | 0.1 |
| | Methyl ethyl ketone | 50 | 50 | 50 | 50 | 50 | 50 | 50 | 50 |

| | | | | | | | | |
|---|---|---|---|---|---|---|---|---|
| Hydroxyl value of photosensitive resin | 1.0 | 1.0 | 1.0 | 17.6 | 17.6 | 17.6 | 18.1 | 1.0 |
| composition (mgKOH/g) | | | | | | | | |

*²Indicates parts by mass of binder polymer after removal of solvent.

TABLE 5

| | | Example | | | |
|---|---|---|---|---|---|
| | | 17 | 18 | 19 | 20 |
| Component | (A1) | 55*² | 55*² | 55*² | 55*² |
| (A) | (A2) | — | — | — | — |
| | (A6) | — | — | — | — |
| | (A7) | — | — | — | — |
| | (A8) | — | — | — | — |
| Component | DPHA | — | 45 | 45 | — |
| (B) | TMPTA | 45 | — | — | — |
| | A-TMMT | — | — | — | 30 |
| | RP-1040 | — | — | — | — |
| | BPE-500 | — | — | — | 15 |
| Component | IRGACURE | 3 | — | — | 3 |
| (C) | OXE01 | | | | |
| | LUCIRIN TPO | — | 5 | 5 | — |
| Component | 1HT | — | — | — | — |
| (D) | MMT | — | — | — | — |
| | HAT | — | — | 0.5 | — |
| | 3MT | — | — | — | — |
| | ATT | — | — | — | — |
| | AMT | — | — | — | — |
| Other | Antage W-500 | 0.1 | 0.1 | 0.1 | 0.1 |
| | Methyl ethyl | 50 | 50 | 50 | 50 |
| | ketone | | | | |

| | | | | |
|---|---|---|---|---|
| Hydroxyl value of | 1.0 | 18.1 | 18.1 | 1.0 |
| photosensitive resin | | | | |
| composition (mgKOH/g) | | | | |

*²Indicates parts by mass of binder polymer after removal of solvent.

TABLE 6

| | | Comp. Ex. | | | | | | | |
|---|---|---|---|---|---|---|---|---|---|
| | | 1 | 2 | 3 | 4 | 5 | 6 | 7 | 8 |
| Component | (A1) | 60*² | — | — | — | — | — | — | — |
| (A) | (A2) | — | — | 60*² | — | — | — | — | — |
| | (A3) | — | 60*² | — | — | 60*² | — | — | — |
| | (A4) | — | — | — | 60*² | — | 60*² | — | — |
| | (A5) | — | — | — | — | — | — | 60*² | 60*² |
| Component | DPHA | — | — | — | — | — | — | 40 | — |
| (B) | TMPTA | — | — | — | 40 | — | — | — | 40 |
| | A-9550 | — | — | — | — | — | — | — | — |
| | A-9570 | — | — | — | — | — | 40 | — | — |
| | PET-30 | 40 | 40 | — | — | — | — | — | — |
| | A-TMM-3 | — | — | — | — | 40 | — | — | — |
| | A-TMM-3LM-N | — | — | 40 | — | — | — | — | — |
| Component | IRGACURE | 5 | 5 | 5 | 5 | 5 | 5 | 5 | 5 |
| (C) | OXE 01 | | | | | | | | |
| Component | AMT | 0.5 | 0.5 | — | — | 0.5 | 0.5 | — | — |
| (D) | HAT | — | — | 0.5 | 0.5 | — | — | 0.5 | 0.5 |
| Component | PM-21 | — | — | — | — | — | — | — | — |
| (E) | | | | | | | | | |
| Other | Antage W-500 | 0.1 | 0.1 | 0.1 | 0.1 | 0.1 | 0.1 | 0.1 | 0.1 |
| | Methyl ethyl ketone | 50 | 50 | 50 | 50 | 50 | 50 | 50 | 50 |

| | | | | | | | | |
|---|---|---|---|---|---|---|---|---|
| Hydroxyl value of photosensitive | 42.8 | 66.1 | 43.8 | 73.3 | 66.1 | 99.8 | 60.7 | 45.6 |
| resin composition (mgKOH/g) | | | | | | | | |

*²Indicates parts by mass of binder polymer after removal of solvent.

TABLE 7

| | | Comp. Ex. | | | |
|---|---|---|---|---|---|
| | | 9 | 10 | 11 | 12 |
| Component | (A1) | 60*² | 60*² | 60*² | 60*² |
| (A) | | | | | |
| Component | PET-30 | 40 | 40 | 40 | 40 |
| (B) | | | | | |
| Component | IRGACURE OXE 01 | — | — | — | — |
| (C) | LUCIRIN TPO | — | — | — | — |
| | IRGACURE 184 | 5 | — | — | — |
| | IRGACURE 651 | — | 5 | — | — |
| | N-1717 | — | — | 0.2 | 0.2 |
| | EAB | — | — | 1 | 2 |
| Other | Anlage W-500 | 0.1 | 0.1 | 0.1 | 0.1 |
| | SH30 | 0.1 | 0.1 | 0.1 | 0.1 |
| | Methyl ethyl ketone | 50 | 50 | 50 | 50 |

| | | | | |
|---|---|---|---|---|
| Hydroxyl value of photosensitive | 43.0 | 43.0 | 44.6 | 44.1 |
| resin composition (mgKOH/g) | | | | |

*²Indicates part by mass of binder polymer after removal of solvent.

### Component (A)

(A1): Propyleneglycol monomethyl ether/toluene solution of copolymer with monomer mixing ratio of (methacrylic acid/methyl methacrylate/ethyl acrylate=12/58/30 (mass ratio)), weight-average molecular weight: 65,000, hydroxyl value: 2 mgKOH/g, acid value: 78 mgKOH/g
(A2): Propyleneglycol monomethyl ether/toluene solution of copolymer with monomer mixing ratio of (methacrylic acid/methyl methacrylate/ethyl acrylate=17.5/52.5/30 (mass ratio)), weight-average molecular weight: 80,000, hydroxyl value: 1 mgKOH/g, acid value: 115 mgKOH/g
(A3): Propyleneglycol monomethyl ether/toluene solution of copolymer with monomer mixing ratio of (methacrylic acid/methyl methacrylate/ethyl acrylate/2-hydroxyethyl methacrylate=12/48/30/10 (mass ratio)), weight-average molecular weight: 45,000, hydroxyl value: 43 mgKOH/g, acid value: 78 mgKOH/g
(A4): Propyleneglycol monomethyl ether/toluene solution of copolymer with monomer mixing ratio of (methacrylic acid/methyl methacrylate/ethyl acrylate/2-hydroxyethyl methacrylate=2/28/30/30 (mass ratio)), weight-average molecular weight: 47,000, hydroxyl value: 129 mgKOH/g, acid value: 78 mgKOH/g
(A5): MIS-115 (Propyleneglycol monomethyl ether acetate/methyl lactate solution of compound obtained by reacting 18.6 g of 2-isocyanatoethyl methacrylate with a copolymer obtained by reacting 12 g of methacrylic acid, 11.1 g of N-cyclohexylmaleimide, 27.2 g of dicyclopentanyl methacrylate and 31.1 g of 2-hydroxyethyl methacrylate), weight-average molecular weight: 26,000, hydroxyl value: 80.2 mgKOH/g, acid value: 55 mgKOH/g
(A6): Propyleneglycol monomethyl ether/toluene solution of copolymer with monomer mixing ratio of (methacrylic acid/methyl methacrylate/butyl acrylate/butyl methacrylate=24/43.5/15/17.5 (mass ratio)), weight-average molecular weight: 35,000, hydroxyl value: 1 mgKOH/g, acid value: 156 mgKOH/g
(A7): Propyleneglycol monomethyl ether/toluene solution of copolymer with monomer mixing ratio of (methacrylic acid/methyl methacrylate/butyl methacrylate=30/35/35 (mass ratio)), weight-average molecular weight: 45,000, hydroxyl value: 2 mgKOH/g, acid value: 195 mgKOH/g
(A8): Propyleneglycol monomethyl ether/toluene solution of copolymer with monomer mixing ratio of (methacrylic acid/methyl methacrylate/ethyl acrylate=24/46/30 (mass ratio)), weight-average molecular weight: 45,000, hydroxyl value: 1 mgKOH/g, acid value; 155 mgKOH/g

### Component (B)

DPHA: Dipentaerythritol hexaacrylate (product of Nippon Kayaku Co., Ltd.), hydroxyl value: 40 mgKOH/g
TMPTA: Trimethylolpropane triacrylate (product of Nippon Kayaku Co., Ltd.), hydroxyl value: 0 mgKOH/g
A-9550: Dipentaerythritol polyacrylate (product of Nippon Kayaku Co., Ltd.), hydroxyl value: 40 mgKOH/g
A-9570: Dipentaerythritol polyacrylate (product of Nippon Kayaku Co., Ltd.), hydroxyl value: 70 mgKOH/g
PET-30: Pentaerythritol triacrylate (product of Nippon Kayaku Co., Ltd.), hydroxyl value: 110 mgKOH/g
A-TMM-3: Pentaerythritol triacrylate (product of Shin-Nakamura Chemical Co., Ltd.), hydroxyl value: 110 mgKOH/g
A-TMM-3LM-N: Pentaerythritol triacrylate (product of Shin-Nakamura Chemical Co., Ltd.), hydroxyl value: 114 mgKOH/g
A-TMMT: Pentaerythritol tetraacrylate (product of Shin-Nakamura Chemical Co., Ltd.), hydroxyl value: 0 (mgKOH/g)
RP-1040: EO-modified pentaerythritol tetraacrylate (product of Nippon Kayaku Co., Ltd.), hydroxyl value: 0 (mgKOH/g)
BPE-500: Ethoxylated bisphenol A dimethacrylate (product of Shin-Nakamura Chemical Co., Ltd.), hydroxyl value: 0 (mgKOH/g)

### Component (C)

IRGACURE OXE 01: 1,2-Octanedione, 1-[(4-phenylthio)-, 2-(O-benzoyloxime)] (product of BASF)
LUCIRIN TPO: 2,4,6-Trimethylbenzoyl-diphenyl-phosphine oxide (product of BASF)
IRGACURE 184: 1-Hydroxy-cyclohexyl-phenyl-ketone (product of BASF)
IRGACURE 651: 2,2-Dimethoxy-1,2-diphenylethan-1-one (product of BASF)
N-1717: 1,7-bis(9-Acridinyl)heptane (product of ADEKA Corp.)
EAB: 4,4′-bis(Diethylamino)benzophenone (product of Hodogaya Chemical Co., Ltd.)

### Component (D)

AMT: 3-Amino-5-mercaptotriazole (product of Wako Pure Chemical Industries, Ltd.)
HAT: 5-Amino-1H-tetrazole (product of Toyobo, Ltd.)
1HT: 1H-Tetrazole (product of Toyobo, Ltd.)
MMT: 1-Methyl-5-mercapto-1H-tetrazole (product of Toyobo, Ltd.)
3MT: 3-Mercapto-triazole (product of Wako Pure Chemical Industries, Ltd.)
ATT: 2-Amino-5-mercapto-1,3,4-thiadiazole (product of Wako Pure Chemical Industries, Ltd.)

### Component (E)

PM21: Phosphoric acid ester containing photopolymerizable unsaturated bond (product of Nippon Kayaku Co., Ltd.)

### Other Components

Antage W-500: 2,2′-Methylene-bis(4-ethyl-6-tert-butylphenol) (product of Kawaguchi Chemical Industry Co., Ltd.)
SH30: Octamethylcyclotetrasiloxane (product of Dow Corning Toray) Methyl ethyl ketone: product of Tonen Chemical Co., Ltd.

TABLE 8

| | Example | | | | | | | |
|---|---|---|---|---|---|---|---|---|
| | 1 | 2 | 3 | 4 | 5 | 6 | 7 | 8 |
| Minimum transmittance | 94 | 93 | 94 | 94 | 94 | 93 | 93 | 94 |
| at 400-700 nm (%) | | | | | | | | |
| Salt spray test | B | C | C | B | B | C | B | C |
| Development residue | A | B | B | B | A | B | B | B |
| Cross-cut adhesion | B | B | B | A | A | B | A | B |

TABLE 9

| | Example | | | | | | | |
|---|---|---|---|---|---|---|---|---|
| | 9 | 10 | 11 | 12 | 13 | 14 | 15 | 16 |
| Minimum transmittance | 94 | 93 | 94 | 94 | 93 | 93 | 94 | 94 |
| at 400-700 nm (%) | | | | | | | | |
| Salt spray test | B | B | B | B-C | B | A | B | A |
| Development residue | C | C | C-D | A | A | C | A | B-C |
| Cross-cut adhesion | B | B | A | A | B | A | A | B |

TABLE 10

| | Example | | | |
|---|---|---|---|---|
| | 17 | 18 | 19 | 20 |
| Minimum transmittance at 400-700 nm | 94 | 95 | 95 | 94 |
| (%) | | | | |
| Salt spray test | B | B-C | B | B-C |
| Development residue | C-D | B | A | B |
| Cross-cut adhesion | A | A | A | A |

TABLE 11

| | Comp. Ex. | | | | | | | |
|---|---|---|---|---|---|---|---|---|
| | 1 | 2 | 3 | 4 | 5 | 6 | 7 | 8 |
| Minimum transmittance | 93 | 93 | 93 | 94 | 94 | 94 | 94 | 93 |
| at 400-700 nm (%) | | | | | | | | |
| Salt spray test | C-D | D | C-D | D | D | D | D | C-D |
| Development residue | C | D | C | D | D | D | D | C |
| Cross-cut adhesion | A | A | A | B | B | C | D | A |

TABLE 12

| | Comp. Ex. | | | |
|---|---|---|---|---|
| | 9 | 10 | 11 | 12 |
| Minimum transmittance at 400-700 nm | 95 | 95 | 85 | 80 |
| (%) | | | | |
| Salt spray test | D | D | C-D | C |
| Development residue | A | A | B | B |
| Cross-out adhesion | A | A | A | A |

### EXPLANATION OF SYMBOLS

1: Photosensitive element, 10: support film, 20: photosensitive layer, 22: protective coat, 30: protective film, 100: base material, 101: transparent substrate, 102: touch screen, 103: transparent electrode (X-position coordinate), 104: transparent electrode (Y-position coordinate), 105: lead wiring, 106: connecting electrode, 107: connecting terminal, 110,120: electrodes for touch panel, 122,123: protective coats, 130: photomask, 200: touch panel.

1. A method for forming a protective coat on an electrode for a touch panel comprising:
a first step in which a photosensitive layer comprising a photosensitive resin composition containing a binder polymer, a photopolymerizable compound and a photopolymerization initiator is provided on a base material having an electrode for a touch panel,
a second step in which prescribed sections of the photosensitive layer are cured by irradiation with active light rays, and
a third step in which the sections other than the prescribed sections of the photosensitive layer are removed to form a protective coat comprising the cured sections of the photosensitive layer covering all or a portion of the electrode, wherein the hydroxyl value of the photosensitive resin composition is no greater than 40 mgKOH/g.

2. The method for forming a protective coat on an electrode for a touch panel according to claim 1, wherein the hydroxyl value of the binder polymer is no greater than 50 mgKOH/g.

3. The method for forming a protective coat on an electrode for a touch panel according to claim 1, wherein the hydroxyl value of the photopolymerizable compound is no greater than 90 mgKOH/g.

4. The method for forming a protective coat on an electrode for a touch panel according to claim 1, wherein the acid value of the binder polymer is no greater than 120 mgKOH/g.

5. The method for forming a protective coat on an electrode for a touch panel according to claim 1, wherein the photosensitive resin composition further comprises a phosphoric acid ester that includes a photopolymerizable unsaturated bond.

6. The method for forming a protective coat on an electrode for a touch panel according to claim 1, wherein the photosensitive layer has a minimum visible light transmittance of 90% or greater at 400 to 700 nm.

7. The method for forming a protective coat on an electrode for a touch panel according to claim 1, wherein the photosensitive resin composition further comprises one or more compounds selected from the group consisting of triazole compounds with mercapto groups, tetrazole compounds with mercapto groups, thiadiazole compounds with mercapto groups, triazole compounds with amino groups and tetrazole compounds with amino groups.

8. The method for forming a protective coat on an electrode for a touch panel according to claim 1, wherein the photopolymerization initiator contains an oxime ester compound and/or a phosphine oxide compound.

9. The method for forming a protective coat on an electrode for a touch panel according to claim 1, wherein the first step is a step in which a photosensitive element comprising a support film and a photosensitive layer composed of the photosensitive resin composition provided on the support film, is prepared and the photosensitive layer of the photosensitive element is transferred onto the base material to provide the photosensitive layer.

10. A photosensitive resin composition comprising a binder polymer, a photopolymerizable compound and a photopolymerization initiator,
wherein the hydroxyl value of the photosensitive resin composition is no greater than 40 mgKOH/g and the photosensitive resin composition is used to form a protective coat on an electrode for a touch panel.

11. The photosensitive resin composition according to claim 10, wherein the hydroxyl value of the binder polymer is no greater than 50 mgKOH/g.

12. The photosensitive resin composition according to claim 10, wherein the hydroxyl value of the photopolymerizable compound is no greater than 90 mgKOH/g.

13. The photosensitive resin composition according to claim 10, wherein the acid value of the binder polymer is no greater than 120 mgKOH/g.

14. The photosensitive resin composition according to claim 10, which further comprises a phosphoric acid ester that includes a photopolymerizable unsaturated bond.

15. The photosensitive resin composition according to claim 10, which has a minimum visible light transmittance of 90% or greater at 400 to 700 nm when formed as a protective coat.

16. The photosensitive resin composition according to claim 10, which further comprises one or more compounds selected from the group consisting of triazole compounds with mercapto groups, tetrazole compounds with mercapto groups, thiadiazole compounds with mercapto groups, triazole compounds with amino groups and tetrazole compounds with amino groups.

17. The photosensitive resin composition according to claim 10, wherein the photopolymerization initiator contains an oxime ester compound and/or a phosphine oxide compound.

18. A photosensitive element comprising a support film and a photosensitive layer composed of the photosensitive resin composition according to claim 10 provided on the support film.

19. The photosensitive element according to claim 18, wherein the thickness of the photosensitive layer is no greater than 10 μm.

20. A method for manufacturing a touch panel comprising a step of forming, on a base material with an electrode for a touch panel, a protective coat covering all or a portion of the electrode by the method according to claim 1.
